(19) United States
(12) Patent Application Publication
(10) Pub. No.: US 2022/0037415 A1
(43) Pub. Date: Feb. 3, 2022

(54) DISPLAY DEVICE

(71) Applicant: InnoLux Corporation, Miao-Li County (TW)

(72) Inventor: Hsiao-Lang LIN, Miao-Li County (TW)

(73) Assignee: InnoLux Corporation, Miao-Li County (TW)

(21) Appl. No.: 17/359,660

(22) Filed: Jun. 28, 2021

(30) Foreign Application Priority Data
Jul. 28, 2020 (CN) 202010736353.3

(51) Int. Cl. H01L 27/32; H01L 51/56

(52) U.S. Cl. CPC H01L 27/322; H01L 27/3258; H01L 2227/323; H01L 51/56; H01L 27/3272

(57) ABSTRACT

The present disclosure provides a display device including a substrate, an active element, a light emitting element, a color conversion element, and a light blocking element. The active element containing a channel is disposed on the substrate. The light emitting element is configured to be driven by the active element to emit a first light. The first light emitted from the light emitting element passes through the color conversion element to be converted into a second light which then passes through the substrate, and the channel of the active element is protected by the light blocking element from at least a majority of the second light.

### CROSS REFERENCE TO RELATED APPLICATION

This application claims the benefit of Chinese Patent Application Serial No. 202010736353.3, filed Jul. 28, 2020, the entire content of which is incorporated herein by reference.

### BACKGROUND OF THE DISCLOSURE

### 1. Field of the Disclosure

The present disclosure relates to a display device.

### 2. Description of the Prior Art

With increasing popularity of display devices, performance of the display devices becomes more and more important. For example, consumers pay more and more attention to the demands of wide color gamut. As a result, quantum dots used in the display devices are developed to increase the color gamut. However, self-luminous display devices commonly combined with quantum dots are top emission type, but the quantum dots are not used in the conventional display devices of bottom emission type.

### SUMMARY OF THE DISCLOSURE

An embodiment of the present disclosure provides a display device including a substrate, an active element, a light emitting element, a color conversion element, and a light blocking element. The active element contains a channel and is disposed on the substrate. The light emitting element is configured to be driven by the active element to emit a first light. The first light emitted from the light emitting element passes through the color conversion element to be converted into a second light which then passes through the substrate, and the channel of the active element is protected by the light blocking element from at least a majority of the second light.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of a display device according to a first embodiment of the present disclosure.

FIG. 2 to FIG. 5 schematically illustrate cross-sectional views of the active elements and the first light blocking layers according to different variant embodiments of the first embodiment of the present disclosure.

FIG. 6 schematically illustrates a cross-sectional view of a display device according to a second embodiment of the present disclosure.

FIG. 7 schematically illustrates a cross-sectional view of a display device according to a third embodiment of the present disclosure.

FIG. 8 schematically illustrates a cross-sectional view of a display device according to a fourth embodiment of the present disclosure.

FIG. 9 schematically illustrates a cross-sectional view of a display device according to a fifth embodiment of the present disclosure.

FIG. 10 schematically illustrates a cross-sectional view of a display device according to a sixth embodiment of the present disclosure.

FIG. 11 schematically illustrates a cross-sectional view of a display device according to the seventh embodiment of the present disclosure.

FIG. 12 and FIG. 13 schematically illustrate a manufacturing method of a display device according to an eighth embodiment of the present disclosure.

FIG. 14 and FIG. 15 schematically illustrate a manufacturing method of a display device according to a ninth embodiment of the present disclosure.

FIG. 16 to FIG. 23 schematically illustrate a manufacturing method of a display device according to a tenth embodiment of the present disclosure.

FIG. 24 to FIG. 26 schematically illustrate a method of forming a color filter according to some embodiments of the present disclosure.

FIG. 27 schematically illustrates a method of forming a planarization layer and a protection layer on the color filter according to some embodiments of the present disclosure.

FIG. 28 schematically illustrates a method of forming a second light blocking layer according to some embodiments of the present disclosure.

FIG. 29 to FIG. 31 schematically illustrate a method of forming a color conversion element and a filling element according to some embodiments of the present disclosure.

FIG. 32 schematically illustrates a method of forming a planarization layer and a protection layer on the second light blocking layer and the color conversion element according to some embodiments of the present disclosure.

FIG. 33 schematically illustrates a method of forming a via structure according to some embodiments of the present disclosure.

FIG. 34 schematically illustrates via structures according to some embodiments of the present disclosure.

### DETAILED DESCRIPTION

The contents of the present disclosure will be described in detail with reference to specific embodiments and drawings. In order to make the contents clearer and easier to understand, the following drawings may be simplified schematic diagrams, and elements therein may not be drawn to scale. The numbers and sizes of the elements in the drawings are just illustrative, and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following description and claims, the terms “comprise”, “include” and “have” are open-ended fashion, so they should be interpreted as “including but not limited to . . . ”.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure. It should be understood that the elements in the drawings may be disposed in any kind of formation known by one skilled in the related art to describe the elements in a certain way. Furthermore, when one element or one layer is called “on” another element or another layer, or called “connected to” another element or another layer, it may be understood that the one element or the one layer is “directly on” the another element or the another layer, or “directly connected to” the another element or the another layer, or another element or another layer may be sandwiched between the one element and the another element or between the one layer and the another layer (indirectly). On the contrary, when the one element or the one layer is called “directly on” or “directly connected to” the another element or the another layer, it may be understood that there is no other elements or layers sandwiched between the one element and the another element or between the one layer and the another layer.

When ordinal numbers, such as “first” and “second”, used in the specification and claims are used to modify elements in the claims, they do not mean and represent that the claimed elements have any previous ordinal numbers, nor do they represent the order of a claimed element and another claimed element, or the order of manufacturing methods. These ordinal numbers are just used to distinguish a claimed element with a certain name from another claimed element with the same name.

In this document, the terms “about”, “substantially” and “approximately” usually mean within 15% of a given value or range, such as within 10%, 5%, 3%, 2%, 1% or 0.5%. The quantity given here is about the quantity, that is, without specifying “about”, “substantially” and “approximately”, the meanings of “about”, “substantially” and “approximately” may still be implied.

It should be noted that the technical features in different embodiments described in the following may be replaced, recombined, or mixed with one another to constitute another embodiment without departing from the spirit of the present disclosure.

The display device of the present disclosure may include light emitting device, sensing device, touch display, curved display or free shape display, but not limited thereto. The display device may include foldable display device or flexible display device. The display device may for example be a tiled display device, but not limited thereto. It should be noted that the display device may be the combinations of the above-mentioned display devices, but not limited thereto. The display device may be applied to any electronic product or electronic device that requires light source, light emission, or display equipment, for example but not limited thereto, televisions, tablet computers, laptops, mobile phones, cameras, wearable devices, electronic entertainment devices, etc.

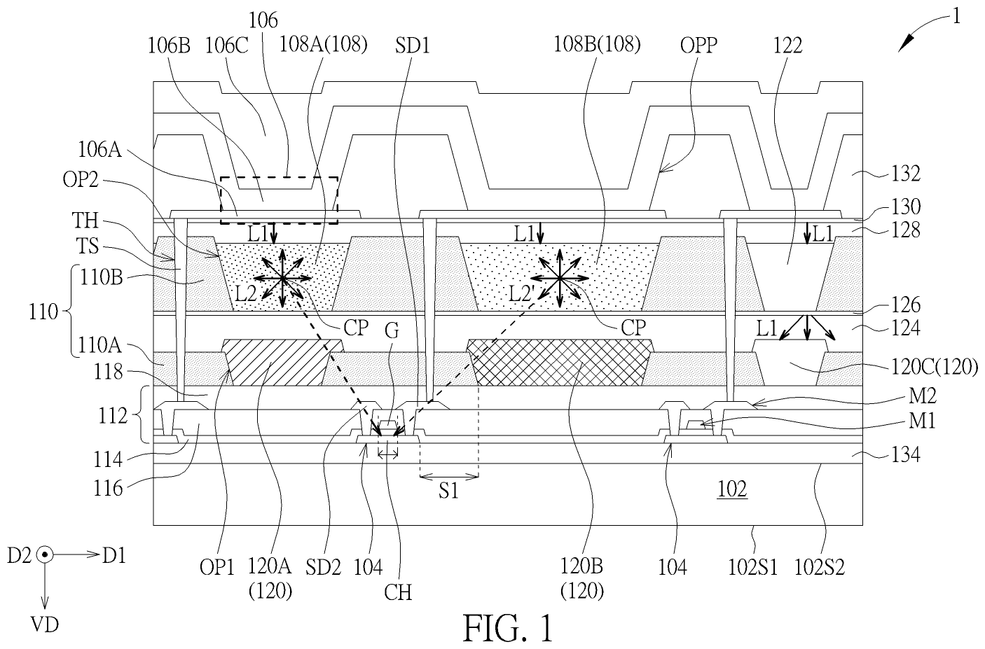

FIG. 1 schematically illustrates a cross-sectional view of a display device according to a first embodiment of the present disclosure. In order to clearly show main features of the present disclosure, the drawings in the present disclosure just show cross-sectional views of apart of the display device, but not limited thereto. As shown in FIG. 1, the display device 1 provided in this embodiment may include a substrate 102, an active element 104, a light emitting element 106, a color conversion element 108, and a light blocking element 110, in which the active element 104, the light emitting element 106, the color conversion element 108, and the light blocking element 110 may be disposed on the substrate 102. The light emitting element 106 may be configured to be driven by the active element 104 to emit first light L1, so that the first light L1 emitted from the light emitting element 106 may pass through the color conversion element 108 to be converted into second light L2, L2′, and the second light L2, L2′ may then pass through the substrate 102 and be emitted from a lower surface 102S1 of the substrate 102 opposite to the light emitting element 106. Therefore, the display device 1 may be of a so-called bottom emission type display device, for example. It should be noted that the second light L2, L2′ generated by the color conversion element 108 after absorbing the first light L1 may not have directionality, that is, moving direction of the second light L2, L2′ may be different from that of the first light L1. For this reason, in the present disclosure, in order to mitigate or avoid electrical deviation (e.g., deviation of threshold voltage) or electric leakage of the active element 104 caused by being irradiated by the second light L2, L2′, the channel CH of the active element 104 may be a part of a semiconductor layer corresponding to a gate G (as shown in FIG. 1). Since electrical deviation (e.g., deviation of threshold voltage) or electric leakage of the channel CH may occur while the channel CH is irradiated by the second light L2, L2′, the channel CH may be protected by the light blocking element 110 from at least a majority of the second light L2, L2′. Further, operation of the display device 1 may meet requirements. In one of manners for the channel CH of the active element 104 being protected by the light blocking element 110 from the at least a majority of the second light L2, L2′, a straight line may be drawn from a center point CP of the color conversion element 108 to any point of the channel CH of the active element 104 (the straight line represents any optical path of the second light L2, L2′), and any part of the light blocking element 110 included (or crossed) by the straight line may allow the channel CH of the active element 104 to be protected by the light blocking element 110 from the at least a majority of the second light L2, L2′, but this embodiment is not limited to this.

Specific structure of the display device 1 provided in this embodiment may be described in the following content. In the embodiment of FIG. 1, the active element 104, the light emitting element 106, the color conversion element 108 and the light blocking element 110 may be disposed on the same side of the substrate 102, but not limited thereto. The substrate 102 may include, for example, a flexible substrate or a non-flexible substrate. The material of the substrate 102 may include, for example, glass, ceramic, quartz, sapphire, acrylic, polyimide (PI), polyethylene terephthalate (PET), polycarbonate (PC), polyether sulfone (PES), polybutylene terephthalate (PBT), polyethylene naphthalate (PEN) or polyarylate (PAR), other suitable materials or combinations thereof, but not limited thereto.

As shown in FIG. 1, the active element 104 may be disposed between the light blocking element 110 and the substrate 102, and the color conversion element 108 may be located on the active element 104, so that at least a part of the light blocking element 110 may be disposed between the color conversion element 108 and the channel CH of the active element 104. Therefore, the light blocking element 110 may block the second light L2, L2′ generated from the color conversion element 108 to reduce or avoid influence of the second light L2, L2′ on electric property of the active element 104. For example, a projection of the light blocking element 110 onto a plane (e.g., an upper surface 102S2 of the substrate 102) along a normal direction VD may have a projection edge, a projection of the channel CH projected onto the same plane (e.g., the upper surface 102S2 of the substrate 102) along the normal direction VD may have another projection edge, and a distance S1 between the two projection edges of the same side of the light blocking element 110 and the channel CH may range from 0.5 micrometers (μm) to 5 μm. The distance S1 may be a shortest distance between the two projection edges. In FIG. 1, the distance S1 may be any distance (spacing) in a direction parallel to the upper surface 10252 of the substrate 102, and the direction parallel to the upper surface 10252 may be, for example, a first direction D1 or a second direction D2.

In one embodiment, the display device 1 may include an active element layer 112 disposed between the light blocking element 110 and the substrate 102 and between the color conversion element 106 and the substrate 102, and the active element layer 112 may be used to control the switch of the light emitting element 106 and the brightness of the first light L1, such that the display device 1 may display images. A plurality of active elements 104 may be disposed and included in the active element layer 112, and the active elements 104 may be electrically connected to the light emitting elements 106 to drive the corresponding light emitting elements 106. Each of the active elements 104 may include a channel CH, and current passing through the channel CH or voltage across the channel CH may be controlled by adjusting electric charges in the channel CH, thereby controlling the switch of the light emitting elements 106 and the brightness of the first light L1. The active elements 104 in FIG. 1 may be, for example, driving elements, but not limited thereto. In FIG. 1, one of the active elements 104 may be electrically connected to one of the light emitting elements 106, but not limited thereto. In some embodiments, one of the active elements 104 may also be electrically connected to a plurality of light emitting elements 106 corresponding to the color conversion elements 108 that generate second light L2, L2′ of the same color.

In some embodiments, a structure of the active element layer 112 is not limited to that shown in FIG. 1, but may further include a plurality of signal lines and a plurality of switching elements (not shown). The signal lines may, for example, include data lines, scan lines, and power lines. The switching elements may be electrically connected to the corresponding active elements 104 to control the electric charges in the channels CH. In some embodiments, the active element layer 112 may further include a circuit for controlling the display device 1, such as a gate driving circuit, but not limited thereto. In some embodiments, the switching elements may be disposed between the light blocking element 110 and the substrate 102 in the normal direction VD of the substrate 102 so as to reduce or avoid influence of the second light L2, L2′ on the electrical properties of the switching elements. In some embodiments, the active element layer 112 may include a 7T2C type of a pixel circuit (i.e., including seven thin film transistors and two capacitors), a 7T3C type of a pixel circuit (i.e., including seven thin film transistors and three capacitors), a 3T1C type of a pixel circuit (i.e., including three thin film transistors and one capacitor), a 3T2C type of a pixel circuit (i.e., including three thin film transistors and two capacitors) or other suitable types of pixel circuit architecture.

For example, the active element 104 and/or the switching element may be a thin film transistor, but not limited thereto. The active element 104 shown in FIG. 1 may be a top-gate thin film transistor as an example. The active element layer 112 may include the channel CH, a first insulating layer 114, a first metal layer M1, a second insulating layer 116, and a second metal layer M2. The first insulating layer 114 may be disposed on the channel CH and serve as a gate insulating layer of the active element 104. The first metal layer M1 is disposed on the first insulating layer 114 and may, for example, form the gate G of the active element 104 and a scan line electrically connected to the gate G. The second insulating layer 116 is disposed on the first insulating layer 114 and the first metal layer M1, and the second metal layer M2 is disposed on the second insulating layer 116 and may, for example, form a source(drain) electrode SD1 and a drain(source) electrode SD2 of the active element 104 and a data line electrically connected to the drain(source) electrode SD2. The second insulating layer 116 may have through holes, such that the source(drain) electrode SD1 and the drain(source) electrode SD2 may be electrically connected to the channel CH through the through holes. In some embodiments, transistor structure of the active element 104 is not limited to the mentioned above, and may be, for example, a bottom-gate type transistor, or may be a double-gate transistor or other suitable transistors based on requirements. Alternatively, the channel CH may also include, for example, amorphous silicon (amorphous silicon), low-temperature polysilicon (LTPS), low-temperature polycrystalline oxide (LTPO), or metal-oxide semiconductor, but not limited thereto. With different types of thin film transistors, the number of insulating layers in the display device 1 may be different. In some embodiments, different thin film transistors may include the channels CH of different materials, but not limited thereto. In some embodiments, the channel CH may include, for example, a P-type doped or N-type doped semiconductor, but not limited thereto. In some embodiments, the active element layer 112 may include a planarization layer 118 disposed on the active element 104, such that the elements formed on the active element layer 112 may be formed on a flat surface to reduce defects in the formed elements. In some embodiments, other optical films, such as a quarter wave plate, an anti-reflection layer, or other suitable layers, may be disposed on the lower surface 102S1 of the substrate 102.

In the embodiment of FIG. 1, the light blocking element 110 may include a first light blocking layer 110A and a second light blocking layer 110B, and the first light blocking layer 110A is disposed between the substrate 102 (or the active element layer 112) and the second light blocking layer 110B. The first light blocking layer 110A may be disposed on the active element layer 112 and have a plurality of openings OP1, and the second light blocking layer 110B may be disposed on the first light blocking layer 110A and have a plurality of openings OP2. For example, in the normal direction VD, one of the openings OP2 may correspond to one of the openings OP1, and one of the light emitting elements 106 may correspond to one of the openings OP2, but not limited thereto. In some embodiments, the number of the light emitting elements 106 corresponding to one opening OP2 may be adjusted according to design. In one embodiment, an optical density (OD) of the first light blocking layer 110A and/or an optical density of the second light blocking layer 110B may be greater than 2.5, for example, so as to achieve the function of shielding light or blocking light from penetration. For example, a material of the light blocking element 110, a material of the first light blocking layer 110A and/or a material of the second light blocking layer 110B may include a light-absorbing material, a light-reflecting material or other suitable materials, but not limited thereto. The light-absorbing material may, for example, include a light blocking resin. For example, the light-absorbing material may include a black photoresist material, a black ink material, a photoresist material doped with carbon, titanium, pigment, or dye, an ink material doped with carbon, titanium, pigment or dye or other suitable materials having an insulating property. When the light-absorbing material is applied to the first light blocking layer 110A, a thickness of the first light blocking layer 110A in the normal direction VD may, for example, range from 1.2 micrometers (μm) to 2.5 μm, but not limited thereto. The light-reflecting material may, for example, include metal or other suitable materials. When the light-reflecting material is applied to the first light blocking layer 110A, the thickness of the first light blocking layer 110A may, for example, range from 900 angstroms to 1.2 μm, but not limited thereto. In some embodiments, a thickness of the second light blocking layer 110B may be greater than the thickness of the first light blocking layer 110A, for example. It should be noted that the “thickness” used herein refers to a maximum thickness of an element in the normal direction VD of the substrate 102. In some embodiments, optical microscopy (OM), scanning electron microscope (SEM), thin film thickness profile measuring instrument (a-step), ellipsometer or other suitable methods may be used to measure the thickness of each element. In detail, in some embodiments, the SEM may be used to obtain any cross-sectional image of the structure and to measure the thickness of each element in this image.

In some embodiments, as viewed along the normal direction VD, a top-view shape of the first light blocking layer 110A and/or a top-view shape of the second light blocking layer 110B may be, for example, a mesh shape, a line shape, a block shape, a dot shape, or other suitable shapes. In some embodiments, the shapes of the first light blocking layer 110A and the second light blocking layer 110B in a cross-sectional direction may be, for example, rectangles, trapezoids, or other suitable shapes. The cross-sectional direction may be, for example, the first direction D1 or the second direction D2.

In the embodiment of FIG. 1, the display device 1 may further include a plurality of color filters 120 respectively disposed in the corresponding openings OP1. The color filters 120 and the color conversion elements 108 may be disposed on the same side of the substrate 102, and the color filters 120 may be disposed between the substrate 102 (or the active element layer 112) and the color conversion elements 108 to enhance color purity of the second light L2, L2′ emitted from the substrate 102 or increase color gamut of the display device 1. Furthermore, the color filters 120 may include a first color filter 120A, a second color filter 120B, and a third color filter 120C, which are respectively disposed in the corresponding openings OP1. Moreover, colors of at least two of the first color filter 120A, the second color filter 120B, and the third color filter 120C may be different. For example, the color of the first color filter 120A, the color of the second color filter 120B, and the color of the third color filter 120C may include red, green, yellow, magenta, cyan, blue, colorless or white. When the color of the first color filter 120A is the same as the color of the second color filter 120B, the colors of the first color filter 120A and the second color filter 120B may be, for example, yellow, and the color of the third color filter 120C may be, for example, colorless, white, or blue.

Alternatively, when the first color filter 120A, the second color filter 120B, and the third color filter 120C all have different colors, the color of the first color filter 120A may be, for example, red or magenta, the color of the second color filter 120B may be, for example, green or cyan, and the color of the third color filter 120C may be, for example, blue, colorless, or white, but not limited thereto. For example, the color filters 120 may include photoresist materials or ink materials, but not limited thereto. The “photoresist material” mentioned herein may refer to a material having a photoresist type or a photoresist characteristic.

In the embodiment of FIG. 1, the color conversion element 108 is disposed between the substrate 102 (or the active element layer 112) and the light emitting element 106, and at least a first light blocking layer 110A is disposed between the color conversion element 108 and the channel CH of the active element 104, such that the second light L2, L2′ generated from the color conversion element 108 may be shielded at least by the first light blocking layer 110A. In the normal direction VD, the color conversion element 108 may correspond to the light emitting element 106, so that the first light L1 generated from the light emitting element 106 may enter the corresponding color conversion element 108, and the color conversion element 108 may generate the second light L2, L2′ after absorbing a part of the first light L1. Therefore, the second light L2, L2′ may have a longer peak wavelength in comparison with the first light L1. For example, the first light L1 may be blue light, and the second light L2, L2′ may be red light or green light, but not limited thereto. The color conversion element 108 may include, for example, a phosphor material, a fluorescent material, quantum dots, a color filter material, or other color conversion materials that are capable of converting the color of light, and the color conversion materials mentioned above may be combined in any combination, and not limited thereto. In some embodiments, since the thickness of the second light blocking layer 110B is greater than the thickness of the first light blocking layer 110A, a thickness of the color conversion element 108 disposed in the opening OP2 in the normal direction VD may be greater than that of the color conversion element 108 disposed in the opening OP1. Accordingly, path of the first light L1 transmitting in the color conversion element 108 may be increased, thereby improving color conversion efficiency of the color conversion element 108. In the embodiment of FIG. 1, one color conversion element 108 may correspond to one light emitting element 106, but not limited thereto. In some embodiments, one color conversion element 108 may correspond to multiple light emitting elements 106.

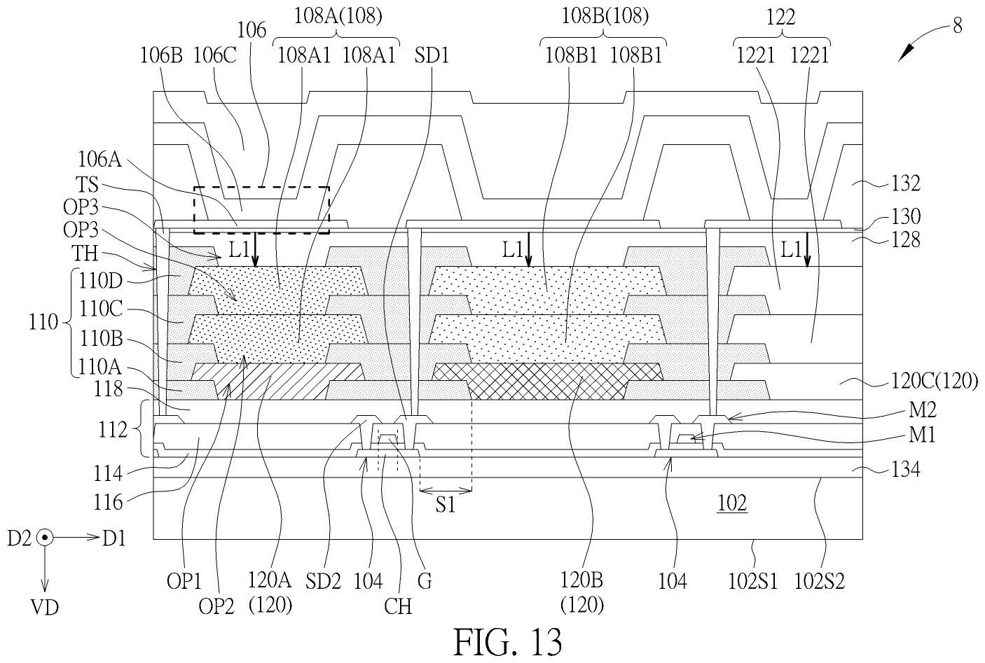

As shown in FIG. 1, the display device 1 may include a plurality of color conversion elements 108, and each color conversion element 108 is disposed in one corresponding opening OP2, so that the second light blocking layer 110B of the light blocking element 110 may be disposed between adjacent two of the color conversion elements 108 and used to block mixing of the second light L2, L2′ of different colors. For example, the color conversion elements 108 may include a first color conversion element 108A and a second color conversion element 108B, and the color of the second light L2 generated from the first color conversion element 108A is different from the color of the second light L2′ generated from the second color conversion element 108B. In one embodiment, the display device 1 may further include a filling element 122 disposed in one of the openings OP2 that does not correspond to the color conversion elements 108. For example, the first color conversion element 108A, the second color conversion element 108B, and the filling element 122 may be respectively disposed in the corresponding openings OP2. Since the filling element 122 is colorless and transparent, the first light L1 generated from the light emitting element 106 may directly pass through the filling element 122 without changing the color, so that the first light L1 may serve as a light of a pixel or a light of a sub-pixel, and the first light L1 and the second light L2, L2′ of different colors may be mixed into white light. For example, the first light L1 may be blue light, the first color conversion element 108A may generate red light, and the second color conversion element 108B may generate green light, but not limited thereto. In the embodiment of FIG. 1, the first color conversion element 108A and the second color conversion element 108B may respectively be a single-layer color conversion layer, but not limited thereto. In some embodiments, the first color conversion element 108A and/or the second color conversion element 108B may include multiple color conversion layers, for example, as shown in FIG. 13. In the embodiment of FIG. 1, the filling element 122 may be a single-layer filling layer, and the filling layer may include transparent resin or other suitable materials, but not limited thereto. In some embodiments, the filling element 122 may also include multiple filling layers. In some embodiments, the filling layer may include the same material as or have the same color as the third color filter 120C. In some embodiments, the filling element 122 may further include scattering particles (not shown) to homogenize the first light L1 emitted from the corresponding opening OP2 toward the substrate 102. The material of the scattering particles may include, for example, titanium dioxide (TiO₂), zinc oxide (ZnO_{X}), or structured particles with scattering characteristics, and not limited thereto.

In some embodiments, as shown in FIG. 1, the display device 1 may further include a planarization layer 124 disposed between the first light blocking layer 110A and the second light blocking layer 110B and between the color filters 120 and the color conversion elements 108, and the planarization layer 124 may have a flat upper surface. It should be noted that the upper surfaces of the color filters 120 and the upper surface of the first light blocking layer 110A may not located on the same plane but have a height difference. Therefore, when the second light blocking layer 110B and the color conversion elements 108 are directly fabricated on an uneven surface, light leakage of the second light blocking layer 110B may easily occur, and light generated from the different color conversion elements 108 may be easily mixed. In the embodiment of FIG. 1, through the installation of the planarization layer 124, the second light blocking layer 110B and the color conversion elements 108 may be disposed on the flat upper surface to reduce or avoid poor formation of the second light blocking layer 110B and the color conversion elements 108, thereby solving the problem of light leakage and light mixing. The planarization layer 124 may, for example, include transparent resin or other suitable materials. In some embodiments, as shown in FIG. 1, the display device 1 may further include a protection layer 126 disposed between the planarization layer 124 and the second light blocking layer 110B or/and between the planarization layer 124 and the color conversion element 108. In this case, the protection layer 126 may be uniformly formed on the planarization layer 124, such that the upper surface of the protection layer 126 may also be flat. The protection layer 126 may include an inorganic material layer, a stack of an organic material layer and an inorganic material layer. For example, the inorganic material layer may include silicon nitride, silicon oxide, silicon oxynitride, aluminum oxide, or other suitable protective materials, or any combination of the inorganic materials mentioned above, but not limited thereto. The organic material layer may include resin, but not limited thereto. In some embodiments, the protection layer 126 may be a single-layer inorganic material layer or a stack of multiple inorganic material layers. In some embodiments, the protection layer 126 may be disposed between the first light blocking layer 110A and the planarization layer 124 and between the color filters 120 and the planarization layer 124.

In some embodiments, as shown in FIG. 1, the display device 1 may further include another planarization layer 128 disposed on the second light blocking layer 110B and the color conversion element 108, and the light emitting elements 106 are disposed on the planarization layer 128. The planarization layer 128 may include the same material as the planarization layer 124, for example, but not limited thereto. In some embodiments, the display device 1 may further include another protection layer 130 disposed between the planarization layer 128 and the light emitting elements 106, in which the protection layer 130 or the planarization layer 128 may prevent water and oxygen from entering the color conversion elements 108 or the filling element 122. In some embodiments, the stacking order of the protection layer 130 and the planarization layer 128 may be interchanged. The protection layer 130 may, for example, include the same material as the protection layer 126, but not limited thereto.

As shown in FIG. 1, the light emitting elements 106 may be disposed on the protection layer 130 (or the planarization layer 128). The light emitting elements 106 may include, for example, an inorganic light emitting diode (organic light emitting diode), an organic light emitting diode (OLED), a mini light emitting diode (mini LED), and a micro light emitting diode (micro LED), quantum dot LED (quantum dot LED, which may include QLED, QDLED), nano wire LED or bar type LED. In some embodiments, the light emitting elements 106 may also include fluorescent material, phosphor material, or other suitable materials, or combinations thereof, but not limited thereto. The light emitting elements 106 in FIG. 1 may take organic light emitting diodes as an example, but not limited thereto. Each of the light emitting elements 106 may include a first electrode 106A, a light emitting layer 106B, and a second electrode 106C, and the light emitting layer 106B is disposed between the first electrode 106A and the second electrode 106C to generate the first light L1. In the embodiment of FIG. 1, the first electrode 106A is disposed on the protection layer 130, and the display device 1 may further include a pixel defining layer 132 disposed on the protection layer 130 and the first electrode 106A, and the pixel defining layer 132 may include a plurality of openings OPP respectively correspond to a plurality of light emitting regions. The pixel defining layer 132 may include, for example, an organic material, but not limited thereto. In one embodiment, the light emitting layers 106B of the different light emitting elements 106 may be a continuous light emitting layer, which extends from an upper surface of the pixel defining layer 132 through sidewalls of the pixel defining layer 132 to the different first electrodes 106A exposed by different openings OPP, and the second electrodes 106C of the different light emitting elements 106 may be a continuous electrode, which is disposed on the continuous light emitting layer 106B. In some embodiments, the light emitting layer 106B and the second electrode 106C disposed on the plurality of first electrodes 106A may include discontinuous regions respectively corresponding to the plurality of first electrodes 106A, but not limited thereto. In the embodiment of FIG. 1, the protection layer 130, the planarization layer 128, the second light blocking layer 110B, the protection layer 126, the planarization layer 124, the first light blocking layer 110A and the planarization layer 118 may have a plurality of through holes TH, and a plurality of via structures TS are disposed in the through holes TH, respectively, such that the first electrode 106A of each of the light emitting elements 106 may be electrically connected to a corresponding one of the active elements 104 through one of the via structures TS in the through hole TH. The via structure TS may include a conductive material, and the conductive material may include, for example, the same material as the first electrode 106A, but not limited thereto. In some embodiments, plural light emitting elements 106 may be disposed in at least one of the openings OPP. In some embodiments, the second electrode 106C may be electrically connected to a driving circuit, but not limited thereto.

In some embodiments, the light emitting element 106 may include a single-layer or multiple-layer light emitting layer 106B, and not limited thereto. In some embodiments, the light emitting element 106 may further include a hole transport layer, a hole injection layer, an electron transport layer, an electron injection layer, and a charge generation layer, which are disposed between the first electrodes 106A and the second electrode 106C, and not limited herein. When the first electrode 106A is an anode, and the second electrode 106C is a cathode, the hole transport layer and the hole injection layer may be disposed between the first electrode 106A and the light emitting layer 106B, and the electron transport layer and the electron injection layer may be disposed between the second electrode 106C and the light emitting layer 106B. When the light emitting element 106 includes a plurality of light emitting layers 106B, the charge generation layer may be disposed between two of light emitting layers 106B, but not limited thereto. In some embodiments, the first electrode 106A and the second electrode 106C may be a cathode and an anode, respectively, but not limited thereto.

The first electrode 106A may include a transparent or semi-transparent conductive material, such as silver (Ag), aluminum (Al), ytterbium (Yb), titanium (Ti), magnesium (Mg), nickel (Ni), lithium (Li), calcium (Ca), copper (Cu), lithium fluoride/gallium (LiF/Ga), lithium fluoride/aluminum (LiF/Al), magnesium silver (MgAg), calcium silver (CaAg), nanosilver glue, other suitable conductive materials, or any combination of the above conductive materials. Since the first electrode 106A, for example, has a thickness of several nanometers to several tens of nanometers, the first electrode 106A may allow light to pass through. The second electrode 106C may include a conductive material with a reflective property, such as silver (Ag), magnesium (Mg), aluminum (Al), platinum (Pt), palladium (Pd), gold (Au), nickel (Ni), neodymium (Nd), iridium (Ir), chromium (Cr), iron (Fe) or other suitable metals, or any combination of the above metals.

In some embodiments, as shown in FIG. 1, the display device 1 may optionally include a buffer layer 134 disposed between the substrate 102 and the active element layer 112. The buffer layer 134 may, for example, be used to block moisture, oxygen or ions from entering the display device 1. The buffer layer 134 may be a single layer or multiple layers. The material of the buffer layer 134 may include, for example, silicon nitride, silicon oxide, silicon oxynitride, aluminum oxide, resin, other suitable materials, or any combination thereof, but not limited thereto.

The display device of the present disclosure is not limited to the above-mentioned embodiment and may include different embodiments or variant embodiments. In order to simplify the description, different embodiments and variant embodiments described below will refer to elements identical to those in the first embodiment using the same labels. For clearly describing different embodiments and variant embodiments, the following contents will describe differences between the first embodiment and different embodiments or variant embodiments, and will no longer repeat descriptions regarding the same elements in detail.

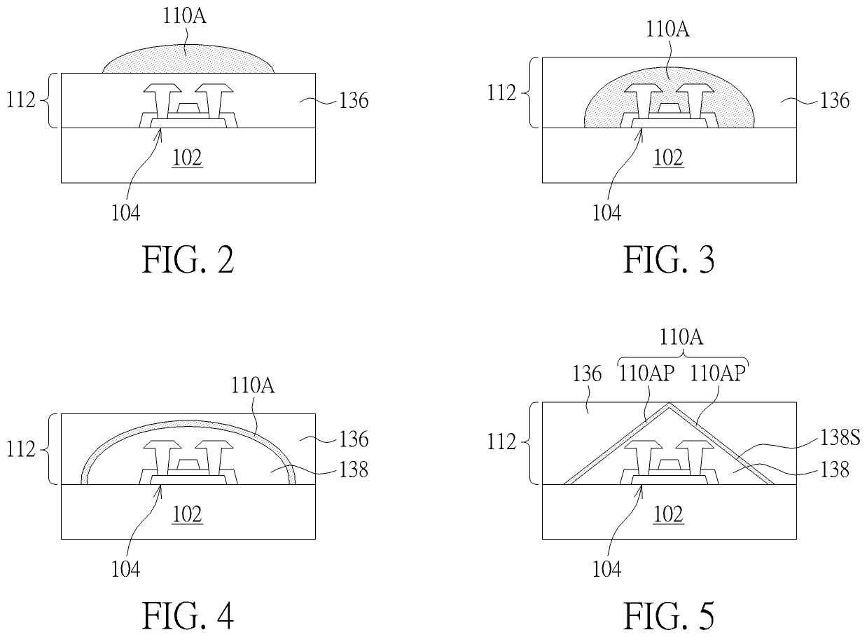

FIG. 2 to FIG. 5 schematically illustrate cross-sectional views of the active elements and the first light blocking layers according to different variant embodiments of the first embodiment of the present disclosure. In a variant embodiment, as shown in FIG. 2, an upper surface of the first light blocking layer 110A along a cross-sectional direction may be, for example, arc-shaped, such that light obliquely incident on the first light blocking layer 110A may encounter the first light blocking layer 110A with a certain thickness. Accordingly, the first light blocking layer 110A with an arc-shaped upper surface may shield more obliquely incident light than the first light blocking layer 110A with a rectangular cross-sectional shape. In this variant embodiment, the active element layer 112 and/or other elements may be similar to or the same as those in FIG. 1 and will not be redundantly described, but not limited thereto.

In another variant embodiment, as shown in FIG. 3, the first light blocking layer 110A may also cover the active element 104 and be disposed in the active element layer 112, thereby blocking the second light entering the active element layer 112 from irradiating the active element 104. In this case, the first light blocking layer 110A may include an insulating light-absorbing material, such as a black photoresist material or a black ink material, but not limited thereto. In addition, the active element layer 112 may include a planarization layer 136 disposed on the first light blocking layer 110A and the substrate 102. In some embodiments, when the first light blocking layer 110A covers the active element 104, the display device 1 may further include another light blocking layer (not shown) disposed on the active element layer 112. The another light blocking layer or the light blocking element may include a light-reflecting material, such as Mo, Al, Cr, or other metal materials, but not limited thereto. In this variant embodiment, the active element layer 112 and/or other elements may be similar to or the same as those in FIG. 1 and will not be redundantly described, but not limited thereto.

In yet another variant embodiment, as shown in FIG. 4, the first light blocking layer 110A may include a light-reflecting metal material, such as Mo, Al, Cr, or other metals, but not limited thereto. In this case, the first light blocking layer 110A may surround the active element 104 and be separated from the active element 104. For example, an insulating layer 138 may be disposed between the first light blocking layer 110A and the active element 104. For example, the first light blocking layer 110A may have an arc cross-sectional shape, but not limited thereto. In this variant embodiment, the active element layer 112 and/or other elements may be similar to or the same as those in FIG. 1 and will not be redundantly described, but not limited thereto.

In further another variant embodiment, as shown in FIG. 5, it is different from FIG. 4 in that the insulating layer 138 may have two flat inclined surfaces 138S, and the first light blocking layer 110A may include at least two inclined flat portions 110AP respectively disposed on the inclined surfaces 138S, so as to shield light from entering the active element 104. An angle between each flat part 110AP and the upper surface 102S2 of the substrate 102 may be an acute angle, and the flat parts 110AP may be connected with each other to form a triangular shape with the upper surface 102S2 of the substrate 102, but not limited thereto. When the first light blocking layer 110A includes metal material, the first light blocking layer 110A may have a better bonding with the flat surface as compared with being formed on a curved surface, so that the bonding between the first light blocking layer 110A and the insulating layer 138 may be improved by forming the first light blocking layer 110A on the flat inclined surfaces 138S. In this variant embodiment, the active element layer 112 and/or other elements may be similar to or the same as those in FIG. 1 and will not be redundantly described, but not limited thereto.

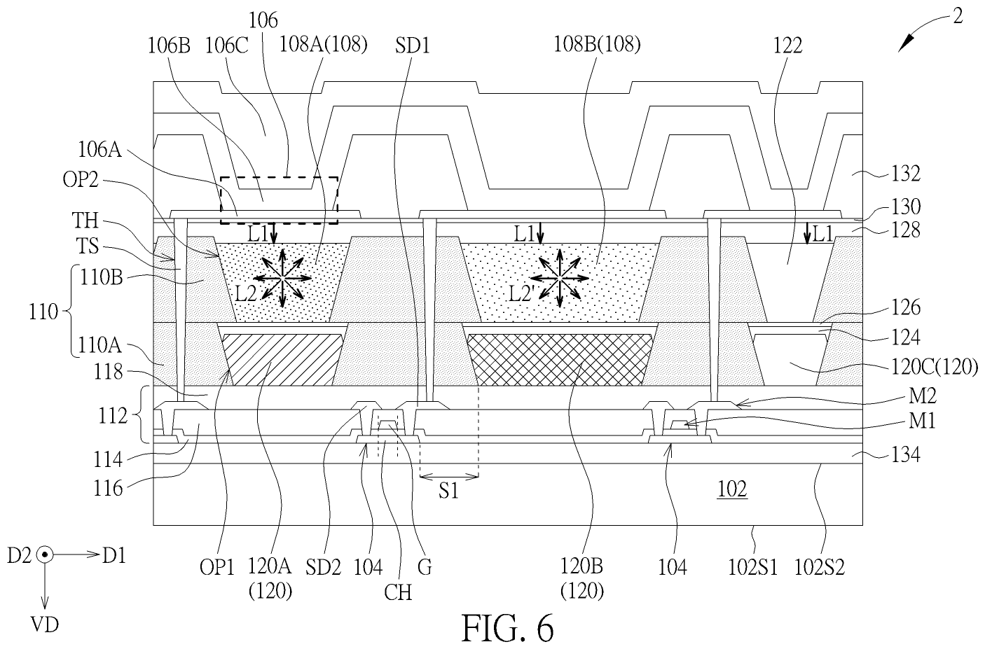

FIG. 6 schematically illustrates a cross-sectional view of a display device according to a second embodiment of the present disclosure. As shown in FIG. 6, the first light blocking layer 110A and the second light blocking layer 110B in this embodiment may be in direct contact with each other; that is, the second light blocking layer 110B may be directly formed on the first light blocking layer 110A. In the embodiment shown in FIG. 6, a thickness of one of the color filters 120 may be smaller than that of the first light blocking layer 110A, so that one of the openings OP1 of the first light blocking layer 110A may not fully filled up with the color filter 120, and the planarization layer 124 and the protection layer 126 may be disposed in remaining space of the opening OP1. In addition, the upper surface of the upmost protection layer 126 in the opening OP1 may be substantially leveled with the upper surface of the first light blocking layer 110A, so that the upper surface of the protection layer 126 and the upper surface of the first light blocking layer 110A may appear a substantially flat surface, so as to improve quality or structural stability of the second light blocking layer 110B coated on the first light blocking layer 110A. In addition, by directly forming the second light blocking layer 110B on the first light blocking layer 110A, the second light L2, L2′ generated from the color conversion element 108 or the first light L2 passing through the filling element 122 may be blocked from being transmitted to another adjacent sub-pixel through the planarization layer 124 and the protection layer 126, thereby reducing color mixing of adjacent sub-pixels. In the embodiment of FIG. 6, since the planarization layer 124 and the protection layer 126 are not disposed between the first light blocking layer 110A and the second light blocking layer 110B, the through hole TH may be disposed in the protection layer 130, the planarization layer 128, the second light blocking layer 110B, the first light blocking layer 110A and the planarization layer 118, but not limited thereto.

In some embodiments, the number of light blocking layers of the light blocking element 110 is not limited to two, and may be three or more. In some embodiments, the stacking order of the planarization layer 124 and the protection layer 126 may be interchanged; that is, the protection layer 126 may be located between the planarization layer 124 and the color filter 120. In this case, the upper surface of the planarization layer 124 may be substantially leveled with the upper surface of the first light blocking layer 110A. In some embodiments, the display device 2 shown in FIG. 6 may adopt any structure or feature of the display device 1 in FIG. 1 or the first light blocking layer 110A of any one of the variant embodiments shown in FIG. 2 to FIG. 5.

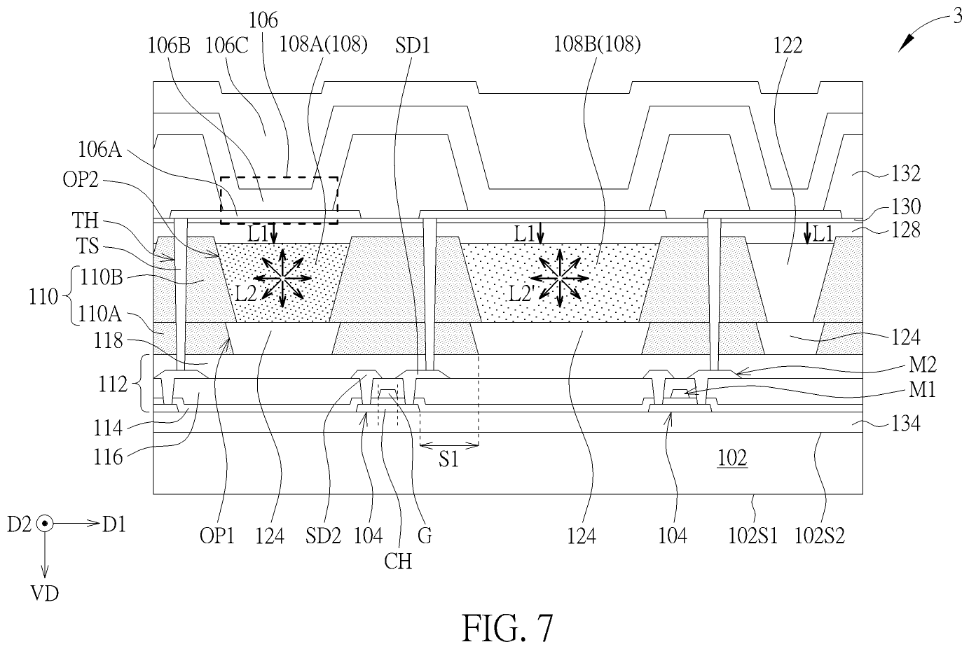

FIG. 7 schematically illustrates a cross-sectional view of a display device according to a third embodiment of the present disclosure. As shown in FIG. 7, the display device 3 provided in this embodiment may not include the color filters, so the planarization layer 124 may be disposed in the openings OP1. The planarization layer 124 may include, for example, a colorless transparent photoresist material, but not limited thereto. In some embodiments, the protection layer 126 may be disposed in the openings OP1. In such case, at least one of the color conversion elements 108 may optionally include color filter pigment. Since the color filter pigment have a scattering function, the color conversion efficiency of the color conversion element 108 may be improved by adding the color filter pigment. In some embodiments, the material of the color conversion element 108 may be quantum dots with high color conversion efficiency to reduce the emission of the first light L1 from a bottom of the color conversion element 108. In some embodiments, the planarization layer 124 may include a distributed Bragg reflector (DBR). Since a degree of the material of the Bragg multilayer film shrinking as temperature changes may be less than that of the color filter, the planarization layer 124 of this case and the first light blocking layer 110A may form a flatter surface to improve quality or structural stability of the second light blocking layer 110B coated on the first light blocking layer 110A. In some embodiments, other elements of the display device 3 shown in FIG. 7 may adopt structures or features in the display device of FIG. 1 or FIG. 6 or the first blocking layer 110A of any one of the variant embodiments shown in FIG. 2 to FIG. 5.

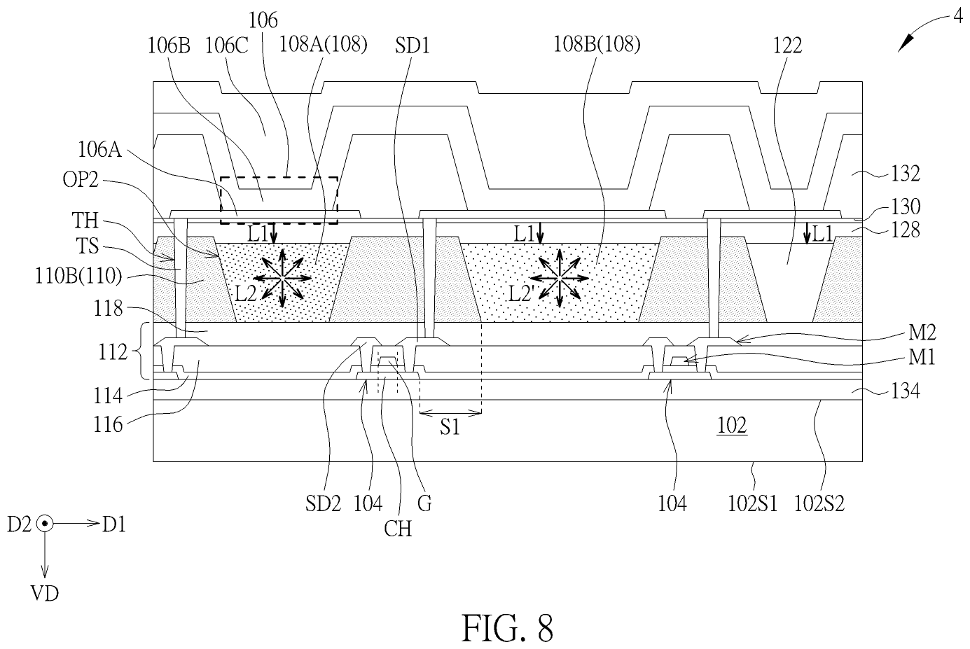

FIG. 8 schematically illustrates a cross-sectional view of a display device according to a fourth embodiment of the present disclosure. As shown in FIG. 8, the display device 4 of this embodiment may not include the color filters 120, the first light blocking layer 110A, the planarization layer 124 and the protection layer 126 shown in FIG. 1. One manner that does not include the color filters 120 is to mix the color filter pigment into the color conversion element 108. In other words, the light blocking element 110 may be formed of the second light blocking layer 110B. In the embodiment of FIG. 8, since the color conversion elements 108 or the filling element 122 and the second light blocking layer 110B are located on the same plane, in order to reduce or avoid the second light L2, L2′ generated from the color conversion elements 108 or the first light L1 passing through the filling element 122 from irradiating the active elements 104, a width of the second light blocking layer 110B located between the adjacent color conversion elements 108 or between the color conversion element 108 and the filling element 122 in a direction parallel to the upper surface 102S2 of the substrate 102 may be wider than a width of the first light blocking layer 110A of FIG. 1 in the same direction. For example, a projection of the second light blocking layer 110B projected on the upper surface 102S2 of the substrate 102 along the normal direction VD may have a projection edge, and a projection of the channel CH projected on the upper surface 102S2 of the substrate 102 along the normal direction VD may have another projection edge, where a distance S1 between the two projection edges of the same side of the second light blocking layer 110B and the channel CH may range from 5.5 μm to 10 μm, and the distance S1 may be a shortest distance between the two projection edges. In some embodiments, the manner of increasing the distance S1 may increase both a width of the upper surface and a width of the lower surface of the second light blocking layer 110B, in which the increment in the width of the upper surface may be less than or equal to the increment in the width of the lower surface. In some embodiments, the manner of increasing the distance S1 may not change the width of the upper surface of the second light blocking layer 110B and may increase the width of the lower surface of the second light blocking layer 110B. In the embodiment of FIG. 8, since the display device 4 may not include the first light blocking layer 110A, the planarization layer 124, and the protection layer 126 in FIG. 1, the through holes TH may be disposed in the protection layer 130, the planarization layer 128, the second light blocking layer 110B, and the planarization layer 118, but not limited thereto. In some embodiments, other elements of the display device 4 shown in FIG. 8 may adopt structures or features of the display device in FIG. 1 or the first light blocking layer 110A of any of the variant embodiments shown in FIG. 2 to FIG. 5.

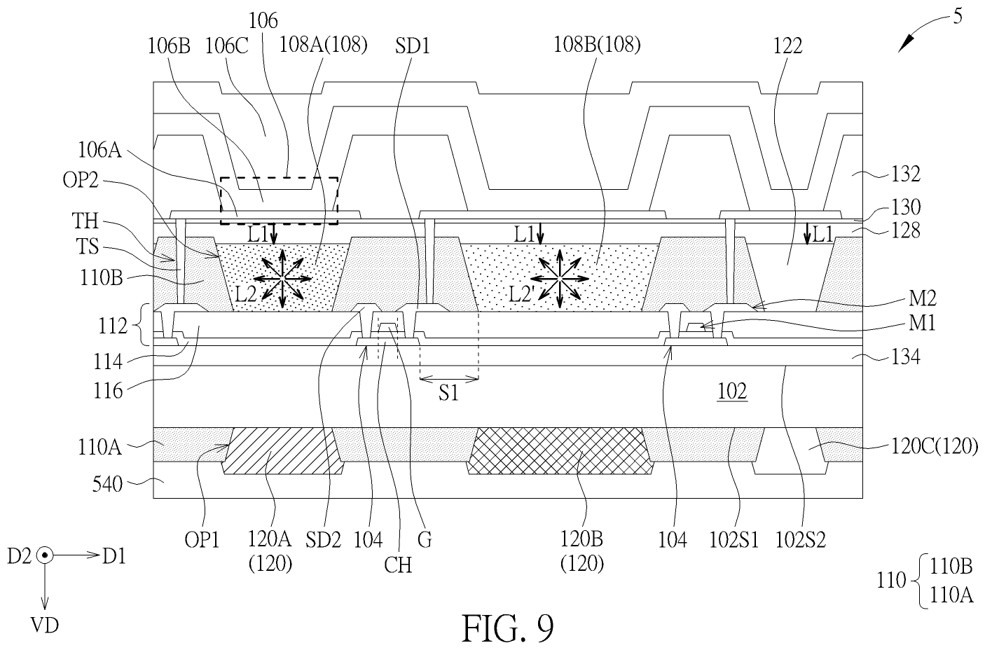

FIG. 9 schematically illustrates a cross-sectional view of a display device according to a fifth embodiment of the present disclosure. As shown in FIG. 9, the color filters 120 and the color conversion elements 108 in the display device 5 of this embodiment are respectively disposed on opposite sides of the substrate 102, that is, on the upper surface 102S2 and the lower surface 102S1 of the substrate 102, respectively. In the embodiment of FIG. 9, the first light blocking layer 110A may be formed on the lower surface 102S1 of the substrate 102 first, and then the color filters 120 are formed in the openings OP1 of the first light blocking layer 110A. Since the flatness of the substrate 102 is better than that of the planarization layer (e.g., the planarization layer 118), disposing the first light blocking layer 110A and the color filters 120 on the lower surface 102S1 of the substrate 102 may improve forming quality or structural stability of the first light blocking layer 110A. In addition, the first light blocking layer 110A has a light blocking function, so that light passing through the upper surface 102S2 of the substrate may not be reflected back to the channels CH. In some embodiments, a planarization layer 540 may be disposed under the first light blocking layer 110A and the color filters 120. In some embodiments, as shown in FIG. 9, the second light blocking layer 110B may be directly formed on the active elements 104, so that the active element layer 112 may not include the planarization layer 118 of FIG. 1, but not limited thereto. In such case, the through holes TH may be disposed in the protection layer 130, the planarization layer 128, and the second light blocking layer 110B, but not limited thereto. In some embodiments, the active element layer 112 may include a planarization layer disposed between the active elements 104 and the second light blocking layer 110B to facilitate formation of the second light blocking layer 110B. In some embodiments, other elements of the display device 5 shown in FIG. 9 may adopt structures or features of the display device in FIG. 1 or the first light blocking layer 110A of any of the variant embodiments shown in FIG. 2 to FIG. 5.

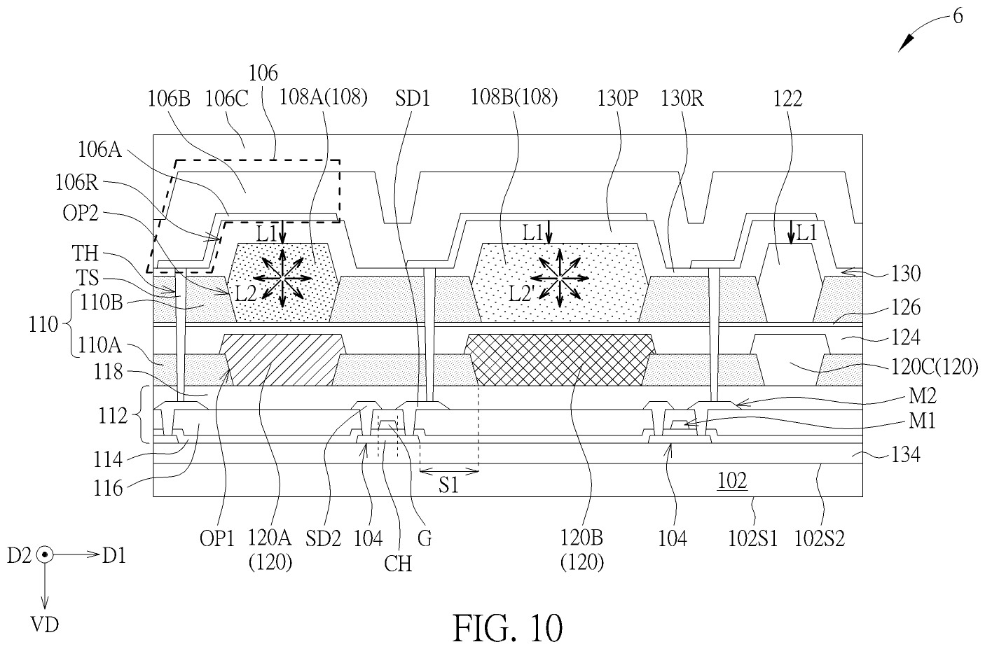

FIG. 10 schematically illustrates a cross-sectional view of a display device according to a sixth embodiment of the present disclosure. As shown in FIG. 10, the light emitting element 106 in the display device 6 of this embodiment may have a light concentrating structure 106R for concentrating the generated first light L1 and emitting it toward the corresponding color conversion element 108 or filling element 122. The light concentrating structure 106R may be, for example, n-shaped (or inverted U-shaped) and may have a notch facing the substrate 102 (or the color conversion element 108). In the embodiment of FIG. 10, the thickness of the color conversion element 108 and the thickness of the filling element 122 may be greater than that of the second light blocking layer 110B, so that the upper surface of the color conversion element 108 may be higher than that of the second light blocking layer 110B. The display device 6 of this embodiment may not include the pixel defining layer, so that the first electrode 106A, the light emitting layer 106B and the second electrode 106C disposed on the color conversion element 108 and the second light blocking layer 110B may extend along the up-and-down contour formed by the upper surface of the color conversion element 108 and the upper surface of the second light blocking layer 110B. Specifically, the display device 6 may further include the protection layer 130 disposed between the first electrode 106A and the color conversion element 108 (or the filling element 122). Since the protection layer 130 is uniformly (or conformally) formed on the second light blocking layer 110B, the color conversion elements 108, and the filling element 122, the upper surface of the protection layer 130 may still have a up-and-down contour. For example, the protection layer 130 may have a plurality of concave portions 130R and a plurality of convex portions 130P alternately connected in sequence. The concave portions 130R are disposed on the second light blocking layer 110B while the convex portions 130P are disposed on the color conversion elements 108 and the filling element 122, respectively. Therefore, the first electrode 106A, the light emitting layer 106B and the second electrode 106C of the light emitting element 106 disposed on one of the convex portions 130P may have a recess with a notch facing downwardly, and the recess may serve as the light concentrating structure 106R. It should be noted that since the thickness of the color conversion element 108 may be increased to be greater than the thickness of the second light blocking layer 110B, the color conversion efficiency of the color conversion element 108 may be improved. In addition, since a region where the light emitting layer 106B of the light emitting element 106 is in contact with both the first electrode 106A and the second electrode 106C may extend along the up-and-down contour, the light emitting region of the light emitting element 106 may be increased to improve the light emitting brightness of the light emitting element 106. In some embodiments, other elements of the display device 6 shown in FIG. 10 may adopt structures or features of the display device shown in FIG. 1 or the first light blocking layer 110A of any of the variant embodiments shown in FIG. 2 to FIG. 5.

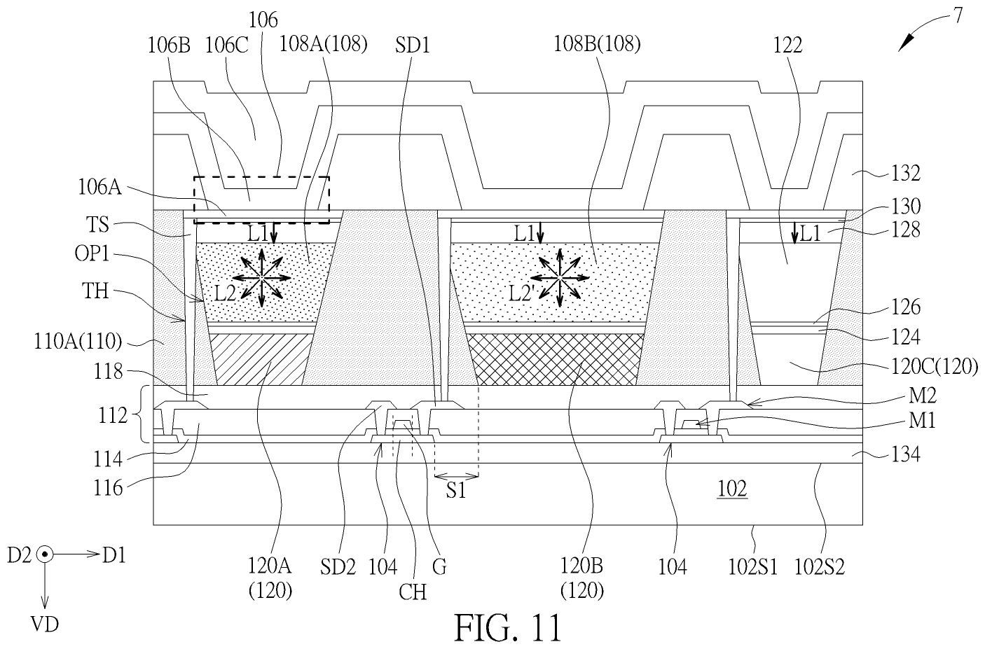

FIG. 11 schematically illustrates a cross-sectional view of a display device according to the seventh embodiment of the present disclosure. As shown in FIG. 11, the thickness of the first light blocking layer 110A in the display device 7 of this embodiment may be greater than a sum of the thickness of one of the color conversion elements 108 and the thickness of one of the color filters 120. For example, the color filter 120 and the color conversion element 108 may include an ink material that is filled into one of the openings OP1 of the first light blocking layer 110A by injection. In some embodiments, since a solvent of the color filter 120 and a solvent of the color conversion element 108 (or the filling element 122) may be different, the protection layer 126 may be disposed between the color filter 120 and the conversion element 108 (or the filling element 122) to prevent the color filter 120 and the color conversion element 108 (or the filling element 122) from affecting each other. In some embodiments, the planarization layer 124 may be further disposed between the color filter 120 and the color conversion element 108 (or the filling element 122). Since the color filter 120 is prone to shrinkage during formation of the color filter 120, which results in an uneven upper surface, disposition of the planarization layer 124 may facilitate the formation of the color conversion element 108 (or the filling element 122). For example, the planarization layer 124 may be disposed between the color filter 120 and the protection layer 126 or between the protection layer 126 and the color conversion element 108 (or the filling element 122). The planarization layer 124 or the protection layer 126 may prevent water and oxygen from entering the color filter 120.

In some embodiments, the planarization layer 128 and the protection layer 130 may further be disposed on the color conversion element 108 (or the filling element 122) in the opening OP1, but not limited thereto. In the embodiment of FIG. 11, the first electrode 106A may be disposed on the protection layer 130 in the opening OP1, so that the upper surface of the first electrode 106A may be substantially leveled with the upper surface of the first light blocking layer 110A to facilitate formation of the pixel defining layer 132 on the first light blocking layer 110A and the first electrode 106A, but not limited thereto. In some embodiments, the protection 130 or the planarization layer 128 may be disposed in the opening OP1, so that the upper surface of the protection layer 130 or the planarization layer 128 may be substantially leveled with the upper surface of the first light blocking layer 110A to facilitate formation of the first electrode 106A and the pixel defining layer 132. In some embodiments, other elements of the display device 7 shown in FIG. 11 may adopt structures or features of the display device in FIG. 1 or the first light blocking layer 110A of any of the variant embodiments shown in FIG. 2 to FIG. 5.

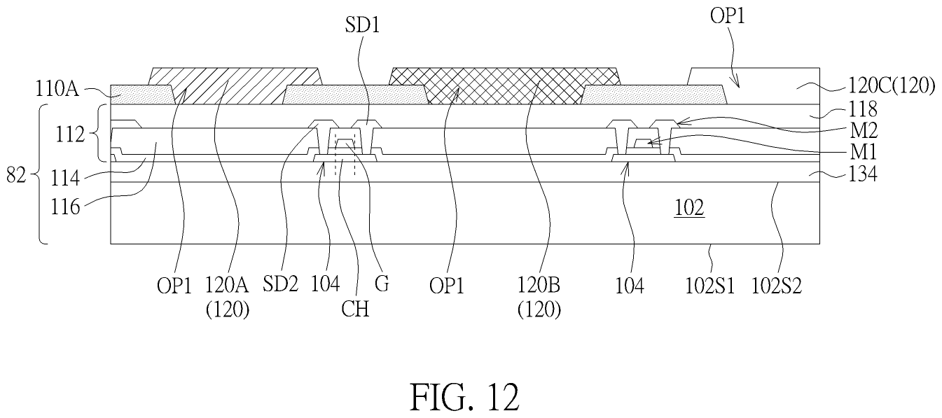

FIG. 12 and FIG. 13 schematically illustrate a manufacturing method of a display device according to an eighth embodiment of the present disclosure, in which FIG. 13 schematically illustrates a cross-sectional view of the display device according to the eighth embodiment of the present disclosure. As shown in FIG. 13, the thickness of the first light blocking layer 110A in the display device 8 of this embodiment may be less than the thickness of the color filter 120. In the embodiment of FIG. 13, the number of light blocking layers of the light blocking element 110 may be different from a sum of the numbers of one of the color filters 120 and the color conversion layers of one of the color conversion elements 108. For example, the number of light blocking layers of the light blocking element 110 may be more than the number of the color conversion layers of one of the color conversion elements 108. For example, the light blocking element 110 may be formed of four light blocking layers, and the color conversion element 108 may be formed of two color conversion layers, but not limited thereto. In the embodiment of FIG. 13, the display device 8 may include the first light blocking layer 110A, the color filter 120, and the color conversion element 108 (or filling element 122), in which the color filter 120 and the color conversion element 108 (or the filling element 122) may be in direct contact with each other, but not limited thereto. In some embodiments, the protection layer (e.g., the protection layer 126 shown in FIG. 6) and/or the planarization layer (e.g., the planarization layer 124 shown in FIG. 6) may further be disposed between the color filter 120 and the color conversion element 108, but not limited thereto. In some embodiments, other elements of the display device 8 shown in FIG. 13 may adopt structures or features in the display device of FIG. 1 or FIG. 6 or the first light blocking layer 110A of any of the variant embodiments shown in FIG. 2 to FIG. 5.

The manufacturing method of the display device 8 shown in FIG. 13 is further described in the following content. As shown in FIG. 12, an active substrate 82 is provided first. The active substrate 82 may include the substrate 102 and the active element layer 112 including the active elements 104. In some embodiments, the active substrate 82 may further include the buffer layer 134 disposed between the substrate 102 and the active element layer 112, but not limited thereto. Since the substrate 102, the active elements 104, the active element layer 112, and the buffer layer 134 may be similar to or the same as the embodiment shown in FIG. 1 or any variant embodiment thereof and does not be repeated herein. In the embodiment of FIG. 12, the method of forming the active substrate 82 may, for example, include forming the buffer layer 134 on the substrate 102 first, and then sequentially forming the channels CH on the buffer layer 134, forming the first insulating layer 114 on the channels CH, forming the first metal layer M1 including the gates G and the scan lines on the first insulating layer 114, forming the second insulating layer 116 on the first metal layer M1 and the first insulating layer 114, forming through holes in the second insulating layer 116 and the first insulating layer 116, forming the second metal layer M2 including the source(drain) electrodes SD1, the drain(source) electrodes SD2 and the data lines on the second insulating layer 116, and forming the planarization layer 118 on the second metal layer M2 and the insulating layer 116. In an embodiment, the source(drain) electrodes SD1 and the drain(source) electrodes SD2 may be disposed in the through holes to be electrically connected to the corresponding channels CH, or conductive materials may be disposed in the through holes to connect the source(drain) electrodes SD1 and the drain(source) electrodes SD2 to the corresponding channels CH. In some embodiments, the method of forming the active substrate 82 may be adjusted according to different types of the active elements 104 or the elements or circuit structures in the active substrate 82.

Subsequently, as shown in FIG. 12, the first light blocking layer 110A may be formed on the active substrate 82, in which the first light blocking layer 110A may have a plurality of openings OP1 to expose the active substrate 82. Next, the first color filter 120A, the second color filter 120B, and the third color filter 120C are respectively formed on the active substrate 82 in the openings OP1. In the embodiment of FIG. 12, the first color filter 120A, the second color filter 120B, and the third color filter 120C may respectively partially extend to the upper surface of the first light blocking layer 110A, and each of which may have a greater thickness than that of the first light blocking layer 110A.

In an embodiment, the colors of at least two of the first color filter 120A, the second color filter 120B, and the third color filter 120C may be different. Since the color of the first color filter 120A, the color of the second color filter 120B, and the color of the third color filter 120C have been described in the embodiment of FIG. 1, they will not be repeated herein. As the colors of the first color filter 120A, the second color filter 120B, and the third color filter 120C change, the first color filter 120A, the method of forming the second color filter 120B, and the third color filter 120C may be different. For example, when the colors of the first color filter 120A, the second color filter 120B, and the third color filter 120C are different from one another, the first color filter 120A, the second color filter 120B, and the third color filter 120C may be formed separately in the corresponding openings OP1, and the order of forming the first color filter 120A, the second color filter 120B, and the third color filter 120C is not limited, and may be any order of the first color filter 120A, the second color filter 120B, and the third color filter 120C. In such case, the first color filter 120A may be, for example, red or magenta, the second color filter 120B may be, for example, green or cyan, and the third color filter 120C may be, for example, blue, colorless, and white, but not limited thereto. When the color of the first color filter 120A is the same as the color of the second color filter 120B, the first color filter 120A and the second color filter 120B may be simultaneously formed in the corresponding openings OP1. Moreover, the order of forming the first color filter 120A and the second color filter 120B and forming the third color filter 120C is not limited. For example, the first color filter 120A and the second color filter 120B may be formed before or after forming the third color filter 120C. In such case, the first color filter 120A and the second color filter 120B may be yellow, for example, and the third color filter 120C may be colorless, white, or blue, for example. In some embodiments, the materials of the color filters 120 may include, for example, a photoresist material or an ink material, but not limited thereto.

Then, as shown in FIG. 13, the second light blocking layer 110B may be formed on the first light blocking layer 110A. In the embodiment of FIG. 13, the second light blocking layer 110B may extend to the upper surfaces of the first color filter 120A, the second color filter 120B, and the third color filter 120C, so that the upper surface of the second light blocking layer 110B may be higher than the upper surfaces of the first color filter 120A, the second color filter 120B, and the third color filter 120C, but not limited to this. The second light blocking layer 110B may have a plurality of openings OP2, respectively exposing the first color filter 120A, the second color filter 120B, and the third color filter 120C.

Next, a first color conversion layer 108A1, a second color conversion layer 108B1, and a filling layer 1221 are respectively formed in the openings OP2. In the normal direction VD of the upper surface 102S2 of the substrate 102, the first color conversion layer 108A1 may overlap the corresponding first color filter 120A, the second color conversion layer 108B1 may overlap the corresponding second color filter 120B, and the filling layer 1221 may overlap the corresponding third color filter 120C. Since the first color conversion layer 108A1, the second color conversion layer 108B1, and the filling layer 1221 include different materials, the first color conversion layer 108A1, the second color conversion layer 108B1, and the filling layer 1221 may be separately formed in the corresponding openings OP2, and the order of forming the first color conversion layer 108A1, the second color conversion layer 108B1, and the filling layer 1221 is not limited and may be any order of the first color conversion layer 108A1, the second color conversion layer 108B1, and the filling layer 1221. In some embodiments, the first color conversion layer 108A1 and the second color conversion layer 108B1 may, for example, include quantum dots with different particle diameters to generate second light of different colors. In some embodiments, the filling layer 1221 may have the same color or include the same material as the third color filter 120C, for example, including a colorless, blue, or white photoresist material, but not limited thereto.

Subsequently, a third light blocking layer 110C may be formed on the second light blocking layer 110B. In the embodiment of FIG. 13, the structure of the third light blocking layer 110C may be similar to the structure of the second light blocking layer 110B; that is, the third light blocking layer 110C may extend to the upper surfaces of the first color conversion layer 108A1, the second color conversion layer 108B1 and the filling layer 1221, and the third light blocking layer 110C may have a plurality of openings OP3 respectively exposing the first color conversion layer 108A1, the second color conversion layer 108B1, and the filling layer 1221. In the embodiment of FIG. 13, after the third light blocking layer 110C is formed, the steps of forming the first color conversion layer 108A1, the second color conversion layer 108B1, and the filling layer 1221 and the step of forming the third light blocking layer 110C may be repeated to form another first color conversion layer 108A1, another second color conversion layer 108B1, and another filling layer 1221 in the openings OP3 of the third light blocking layer 110C, respectively, and to form another third color conversion layer on the third light blocking layer 110C, thereby forming the first color conversion element 108A, the second color conversion element 108B, the filling element 122, and the light blocking element 110. In the embodiment of FIG. 13, the thickness of the light blocking element 110 in the normal direction VD perpendicular to the upper surface 102S2 of the substrate 102 may be greater than a sum of the thickness of one of the color filters 120 and the thickness of one of the color conversion elements 108 in the normal direction VD, but not limited thereto.

The number of repeating the steps of forming the first color conversion layer 108A1, the second color conversion layer 108B1, and the filling layer 1221 and the step of forming the third light blocking layer 110C may depend on the number of the first color conversion layers 108A1, the number of the second color conversion layers 108B1, and the number of filling layers 1221. For example, when the first color conversion element 108A is a single-layer first color conversion layer 108A1, the second color conversion element 108B is a single-layer second color conversion layer 108B1, and the filling element 122 is a single-layer filling layer 1221, it does not need to repeat the steps of forming the first color conversion layer 108A1, the second color conversion layer 108B1, and the filling layer 1221 and the step of forming the third light blocking layer 110C. By analogy, when the first color conversion element 108A includes at least three first color conversion layers 108A1, the second color conversion element 108B includes at least three second color conversion layers 108B1, and the filling element 122 includes at least three filling layers 1221, the steps of forming the first color conversion layer 108A1, the second color conversion layer 108B1, and the filling layer 1221 and the step of forming the third light blocking layer 110C may be repeated at least twice.

Next, as shown in FIG. 13, after the first color conversion element 108A, the second color conversion element 108B, the filling element 122, and the light blocking element 110 are formed, the planarization layer 128 and a protection layer 130 are sequentially formed on the first color conversion element 108A, the second color conversion element 108B, the filling element 122 and the light blocking element 110. In some embodiments, the order of forming the planarization layer 128 and the protection layer 130 may be interchanged, or just one of the planarization layer 128 and the protection layer may be formed on the first color conversion element 108A, the second color conversion element 108B, the filling element 122, and the light blocking element 110.

Then, as shown in FIG. 13, through holes TH are formed in the protection layer 130, the planarization layer 128, the light blocking element 110 and the planarization layer 118 to respectively expose the source(drain) electrodes SD1 of the active elements 104. Next, the via structures TS are disposed in the through holes TH, respectively, and the first electrodes 106A are formed on the via structures TS, respectively. Subsequently, the pixel defining layer 132, the light emitting layer 106B, and the second electrode 106C are formed on the first electrodes 106A and the protection layer 130, thereby forming a plurality of light emitting elements 106 on the first color conversion layer 108A1, the second color conversion layer 108B1, and the filling layer 1221. Accordingly, the display device 8 of this embodiment may be formed.

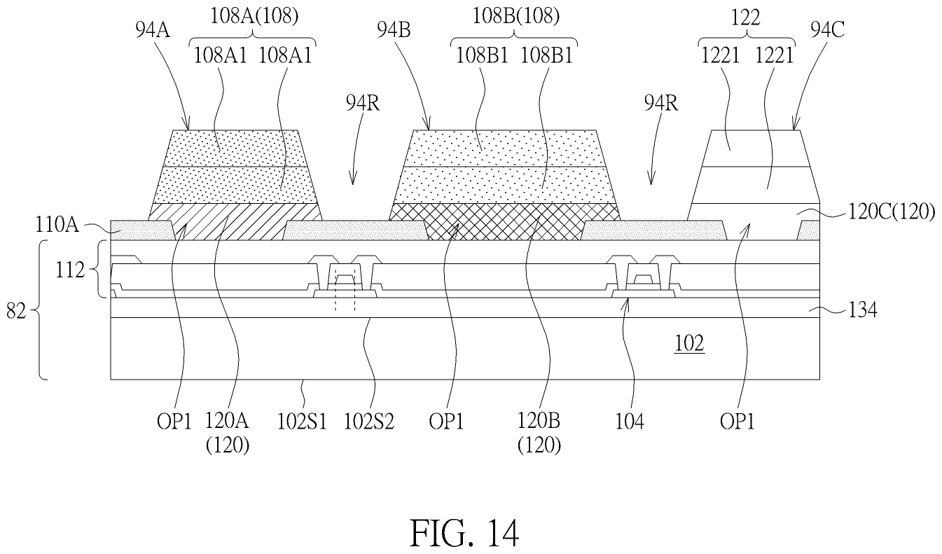

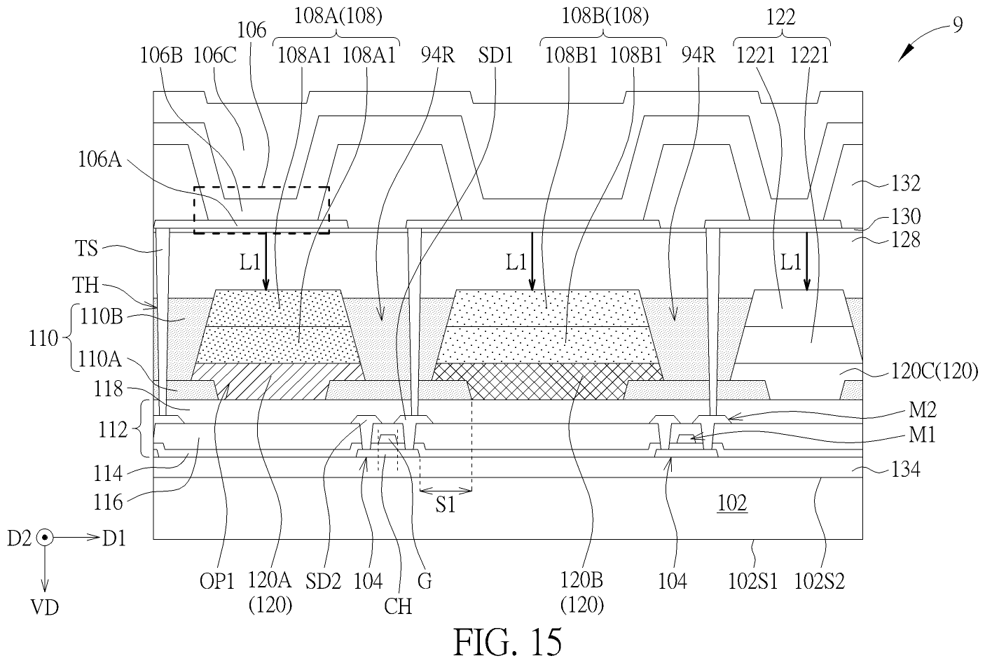

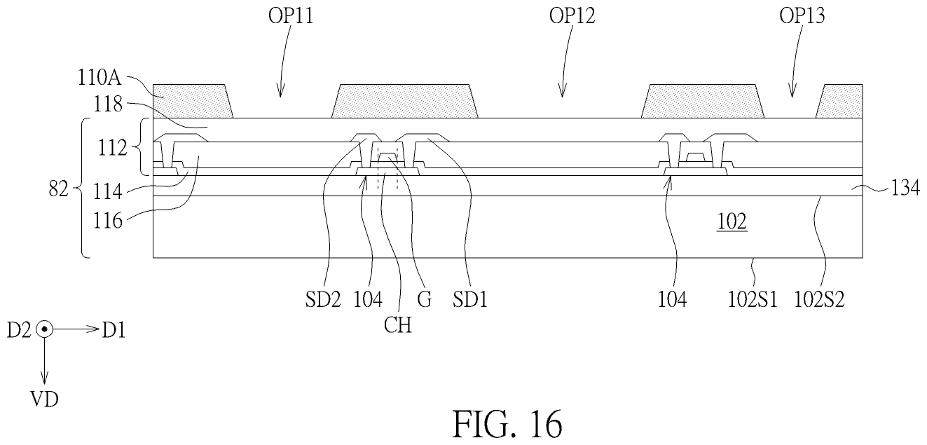

FIG. 14 and FIG. 15 schematically illustrate a manufacturing method of a display device according to a ninth embodiment of the present disclosure, in which FIG. 15 schematically illustrates a cross-sectional view of the display device according to the ninth embodiment of the present disclosure. As shown in FIG. 15, the display device 9 provided in this embodiment differs from the display device 8 shown in FIG. 13 in that the first color conversion element 108A, the second color conversion element 108B and the filling element 122 are formed before the second light blocking layer 110B is formed. In the embodiment of FIG. 15, the number of light blocking layers of light blocking element 110 may be, for example, less than a sum of the number of one of color filters 120 and the number of the color conversion layers of one of the color conversion elements 108. For instance, the light blocking element 110 may be formed of two light blocking layers, while the color conversion element 108 may be formed of two color conversion layers, but not limited thereto. In some embodiments, the upper surface of the light blocking element 110 may be slightly lower than or substantially leveled with the upper surface of the color conversion element 108 and/or the upper surface of the filling element 122, but not limited thereto. The manufacturing method of the display device 9 of this embodiment is specifically described as follows with reference to FIG. 14 and FIG. 15. As shown in FIG. 14, in the manufacturing method of the display device 9 of this embodiment, the steps of providing the active substrate 82 and forming the first light blocking layer 110A may be the same as those of the embodiment shown in FIG. 12 and FIG. 13 and will not be described in detail herein.

In the embodiment shown in FIG. 14, after the first light blocking layer 110A is formed, a first stack 94A, a second stack 94B, and a third stack 94C may be formed on the active substrate 82 in the openings OP1, respectively, in which the first stack 94A may include a first color filter 120A and a first color conversion element 108A disposed on the first color filter 120A, the second stack 94B may include the second color filter 120B and the second color conversion element 108B disposed on the second color filter 120B, and the third stack 94C may include the third color filter 120C and the filler element 122 disposed on the third color filter 120C. Since the upper surfaces of the first stack 94A, the second stack 94B and the third stack 94C may be higher than the upper surface of the first light blocking layer 110A, a recess 94R may be between any two of the first stack 94A, the second stack 94B and the third stack 94C and correspond to the first light blocking layer 110A. The method of forming the first stack 94A, the second stack 94B and the third stack 94C is further described in the following contents. In one embodiment, after the first light blocking layer 110A is formed, the first color filter 120A, the second color filter 120B, and the third color filter 120C may be formed on the active substrate 82 in the openings OP1, respectively. In such case, the first color filter 120A, the second color filter 120B, and the third color filter 120C may be formed in the same manner as the embodiment shown in FIG. 12 and FIG. 13 and will not be repeated herein. Then, one first color conversion layer 108A1 is formed on the first color filter 120A, one second color conversion layer 108B1 is formed on the second color filter 120B, and one filling layer 1221 is formed on the third color filter 120C. The order of forming the first color conversion layer 108A1, the second color conversion layer 108B1 and the filling layer 1221 is not limited, and may be any order of the first color conversion layer 108A1, the second color conversion layer 108B1 and the filling layer 1221. Thereafter, the steps of forming the first color conversion layer 108A1, forming the second color conversion layer 108B1, and forming the filling layer 1221 may be repeated to form another first color conversion layer 108A1 on the first color conversion layer 108A1, form another second color conversion layer 108B1 on the second color conversion layer 108A1, and form another filling layer 1221 on the filling layer 1221, thereby forming the first stack 94A, the second stack 94B, and the third stack 94C. The number of repeating the step of forming the first color conversion layer 108A1, the second color conversion layer 108B1 and the filling layer 1221 may depend on the number of the first color conversion layers 108A1, the number of the second color conversion layers 108B1 and the number of the filling layers 1221. For example, when the first color conversion element 108A is a single-layer first color conversion layer 108A1, the second color conversion element 108B is a single-layer second color conversion layer 108B1, and the filling element 122 is a single-layer filling layer 1221, it does not need to repeat the steps of forming the first color conversion layer 108A1, the second color conversion layer 108B1 and the filling layer 1221. By analogy, when the first color conversion element 108A includes at least three first color conversion layers 108A1, the second color conversion element 108B includes at least three second color conversion layers 108B1, and the filling element 122 includes at least three filling layers 1221, the steps of forming the first color conversion layer 108A1, the second color conversion layer 108B1 and the filling layer 1221 may be repeated at least twice. The materials or colors of the first color filter 120A, the second color filter 120B, the third color filter 120C, the first color conversion layer 108A1, the second color conversion layer 108B1 and the filling layer 1221 may be the same as those of the embodiment of FIG. 12 and FIG. 13 or the embodiment shown in FIG. 1 and will not be repeated again.

The method of forming the first color filter 120A, the second color filter 120B, the third color filter 120C, the first color conversion element 108A, the second color conversion element 108B, and the filling element 122 is not limited to the mentioned above. In some embodiments, as shown in FIG. 14, the first stack 94A, the second stack 94B, and the third stack 94C may be formed separately, and the order of forming the first stack 94A, the second stack 94B, and the third stack 94C may be any order of the first stack 94A, the second stack 94B, and the third stack 94C. For example, after forming the first light blocking layer 110A, the first color filter 120A and the first color conversion element 108A may be sequentially formed on the active substrate 82 in the corresponding opening OP1 to form the first stack 94A, and then the second color filter 120B and the second color conversion element 108B may be sequentially formed on the active substrate 82 in the corresponding opening OP1 to form the second stack 94B. Then, the third color filter 120C and the filling element 122 are sequentially formed on the active substrate 82 in the corresponding opening OP1 to form the third stack 94C. The number of the first color conversion layers 108A1 of the first color conversion element 108a, the number of the second color conversion layers 108B1 of the second color conversion elements 108b, and the number of the filling layers 1221 of the filling elements 122 may be adjusted according to requirements.

In some embodiments, as shown in FIG. 14, two of the first stack 94A, the second stack 94B and the third stack 94C may be formed together. For example, after forming the first light blocking layer 110A, the first color filter 120A and the second color filter 120B may be respectively formed in the corresponding openings OP1 first. Then, the first color conversion element 108A may be formed on the first color filter 120A, and the second color conversion element 108B may be formed on the second color filter 120B to form the first stack 94A and the second stack 94B. After that, the third color filter 120C and the filling element 122 are sequentially formed on the active substrate 82 in the corresponding opening OP1 to form the third stack 94C. Alternatively, in some embodiments, as shown in FIG. 14, after forming the first light blocking layer 110A, the first color filter 120A and the third color filter 120C may be respectively formed in the corresponding openings OP1 first. Then, the first color conversion element 108A may be formed on the first color filter 120A, and the filling element 122 may be formed on the third color filter 120C to form the first stack 94A and the third stack. After that, the second color filter 120B and the second color conversion element 108B are sequentially formed on the active substrate 82 in the corresponding opening OP1 to form the second stack 94B. The method of forming the first stack 94A, the second stack 94B and the third stack 94C in the present disclosure is not limited to the mentioned above.

It should be noted that, in the embodiment shown in FIG. 14, the color filter 120 may, for example, include a photoresist material, so that the first color filter 120A, the second color filter 120B, and the third color filter 120C may partially extend to the upper surface of the first light blocking layer 110A, and respectively have a thickness greater than the thickness of the first light blocking layer 110A. Moreover, since the color conversion layers of the color conversion element 108 may include a photoresist material, the color conversion layers may be directly formed or stacked on the corresponding color filter 120 without a partition wall. In the embodiment of FIG. 14, the first light blocking layer 110A, the color filter 120, the first color conversion layer 108A1, the second color conversion layer 108B1, and the filling layer 1221 may respectively include photoresist materials, so that one of the color filters 120 may directly contact one of the color conversion elements 108 (or the filling layer 1221), but not limited thereto. In some embodiments, the protection layer (e.g., the protection layer 126 shown in FIG. 6) and/or the planarization layer (e.g., the planarization layer 124 shown in FIG. 6) may be further disposed between one of the color filters 120 and the corresponding color conversion element 108, but not limited thereto.

As shown in FIG. 15, after the first stack 94A, the second stack 94B and the third stack 94C are formed, the second light blocking layer 110B may be formed on the first light blocking layer 110A on one side of the first stack 94A, the second stack 94B or the third stack 94C or between any two of the first stack 94A, the second stack 94B and the third stack 94C to form the light blocking element 110, in which the upper surface of the second light blocking layer 110B may be lower than the upper surface of the first stack 94A, the upper surface of the second stack 94B, and the upper surface of the third stack 94C. For example, the second light blocking layer 110B may include an ink material, and when the second light blocking layer 110B is formed, the first stack 94A, the second stack 94B and the third stack 94C may serve as a partition wall, so that the second light blocking layer 110B may be filled in the recess 94R, but not limited thereto. In some embodiments, the second light blocking layer 110B may include a photoresist material.

As shown in FIG. 15, after the second light blocking layer 110B is formed, the planarization layer 128, the protection layer 130, the pixel defining layer 132, and the light emitting elements 106 may be formed on the first stack 94A, the second stack 94B, the third stack 94C, and the second light blocking layer 110B of the light blocking element 110, thereby forming the display device 9 of this embodiment. Since the steps and their variants of forming the planarization layer 128, the protection layer 130, the pixel defining layer 132, and the light emitting elements 106 may be the same as those of the above embodiment shown in FIG. 13, they will not be repeated herein. In some embodiments, other elements of the display device 9 shown in FIG. 15 may adopt structures or features of the display device shown in FIG. 1 or FIG. 6 or the first light blocking layer 110A of any of the variant embodiments shown in FIG. 2 to FIG. 5.

FIG. 16 to FIG. 23 schematically illustrate a manufacturing method of a display device according to a tenth embodiment of the present disclosure. As shown in FIG. 16, the active substrate 82 is first provided. The active substrate 82 may include the substrate 102 and the active element layer 112 including the active elements 104. In some embodiments, the active substrate 82 may further include the buffer layer 134 disposed between the substrate 102 and the active element layer 112, but not limited thereto. The substrate 102, the active elements 104, the active element layer 112, and the buffer layer 134 may be similar to or the same as the embodiment shown in FIG. 1 or its variant embodiments and will not be repeated in detail. In some embodiments, the method of forming the active substrate 82 may be similar to or the same as the embodiment shown in FIG. 12 or other suitable variant methods and will not be repeated herein.

As shown in FIG. 16, the first light blocking layer 110A is formed on the active substrate 82. For example, the method of forming the first light blocking layer 110A may include following steps. First of all, a light blocking photoresist is formed on the active substrate 82 by a spin coating process, a slit coating process or other suitable processes. Then, the light blocking photoresist is dried, for example, through a vacuum drying process. Next, a pre-baking process, i.e. soft baking, is performed on the light blocking photoresist at a temperature ranging from 70° C. to 100° C. Then, an exposure process and a development process are performed on the light blocking photoresist through a photomask to form an opening OP11, an opening OP12, and an opening OP13. Thereafter, a post-baking process, i.e., hard baking, is performed at a temperature ranging from 200° C. to 250° C. to form the first light blocking layer 110A. A shape of the formed first light blocking layer 110A in the cross-sectional direction (e.g., the first direction D1 or the second direction D2) may be, for example, rectangular, trapezoid or other suitable shapes. It should be noted that a top-view area of the opening OP11 and a top-view area of the opening OP12 may be different from each other, for example, widths of the opening OP11 and the opening OP12 in the same cross-sectional direction may be different from each other, so as to control the brightness of light of different colors after passing through the opening OP11 and the opening OP12 to match each other and meet the requirements. For example, when the transmittance of the first color filter 120A formed in the opening OP11 in the subsequent step is greater than that of the second color filter 120B formed in the opening OP12, the top-view area of the opening OP11 may be less than that of the opening OP12. Alternatively, when the light conversion efficiency of the first color conversion element 108A formed on the opening OP11 in the subsequent step is greater than that of the second color conversion element 108B formed on the opening OP12, the top-view area of the opening OP11 may be less than that of the opening OP12. The light conversion efficiency herein may be, for example, a ratio of the brightness of light converted by the color conversion element to the brightness of light irradiating the color conversion element, but not limited thereto. By analogy, the top-view areas of the opening OP11 and the opening OP12 may be used to adjust the brightness of the transmitted light. In some embodiments, a top-view area of the opening OP13 may be different from the top-view area of the opening OP11 and the top-view area of the opening OP12. For example, when a colorless and transparent filling element 122 or a colorless and transparent filling element 122 added with metal particles or scattering particles is disposed in the opening OP13 in the subsequent step, the top-view area of the opening OP13 may be less than the top-view area of the opening OP11 and the top-view area of the opening OP12, but not limited thereto.

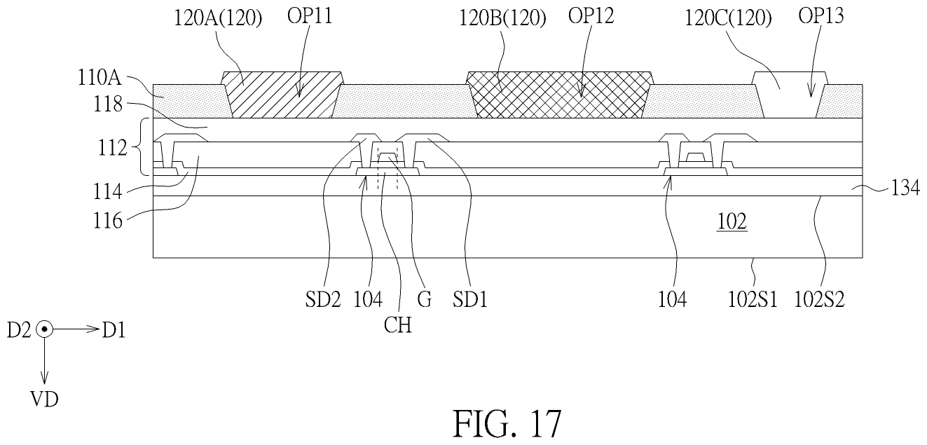

Then, as shown in FIG. 17, the first color filter 120A is formed in the opening OP11, the second color filter 120B is formed in the opening OP12, and the third color filter 120C is formed in the opening OP13. In the embodiment of FIG. 17, the first color filter 120A, the second color filter 120B, and the third color filter 120C may extend partially to the upper surface of the first light blocking layer 110A, respectively, and have a thickness greater than that of the first light blocking layer 110A. In one embodiment, the first color filter 120A, the second color filter 120B, and the third color filter 120C may include photoresist materials. For example, the method of forming at least one of the first color filter 120A, the second color filter 120B, and the third color filter 120C may include following steps. At first, a colored photoresist material or a colorless and transparent photoresist material is formed in the opening OP11, the opening OP12 or the opening OP13 by the spin coating process, the slit coating process or other suitable processes. Then, the photoresist material is dried, such as through a vacuum drying process. Then, the photoresist material is pre-baked at a temperature ranging from 70° C. to 100° C. After that, an exposure process and a development process are performed on the photoresist material through a photomask to keep the photoresist material in the opening OP11, the opening OP12 or the opening OP13. Then, the photoresist material may be optionally irradiated with infrared light to remove some water and oxygen (moisture and/or oxygen) or ions in the photoresist material near its upper surface. In some embodiments, the method of removing water, oxygen or ions is not limited to irradiation with infrared light, and may be other suitable methods. Subsequently, the post-baking process is performed at a temperature ranging from 200° C. to 250° C. to form one of the first color filter 120A, the second color filter 120B, and the third color filter 120C. Then, the above steps are repeated at least twice to form the others of the first color filter 120A, the second color filter 120B, and the third color filter 120C. After that, a de-gas process may be optionally performed to remove or release most of water, oxygen or ions in the first color filter 120A, the second color filter 120B, the third color filter 120C and the first light blocking layer 110A, thereby reducing the influence of water, oxygen or ions on the color conversion elements 108 and/or the light emitting elements 106 formed in the following steps. It should be noted that the de-gas process may not only reduce water, oxygen or ions in one layer near the upper surface of the layer, but also reduce water, oxygen or ions far away from the upper surface of the layer.

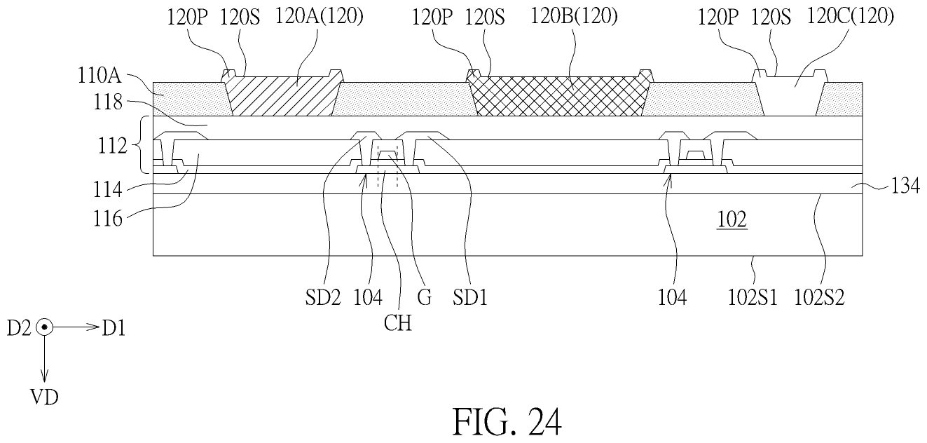

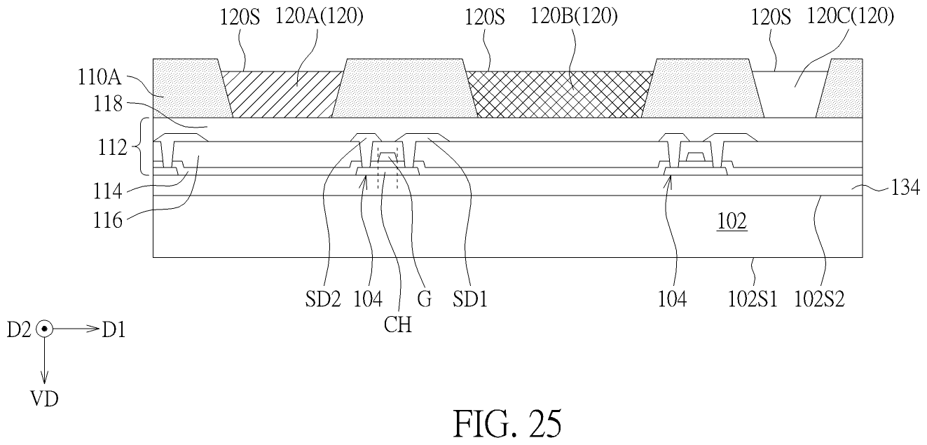

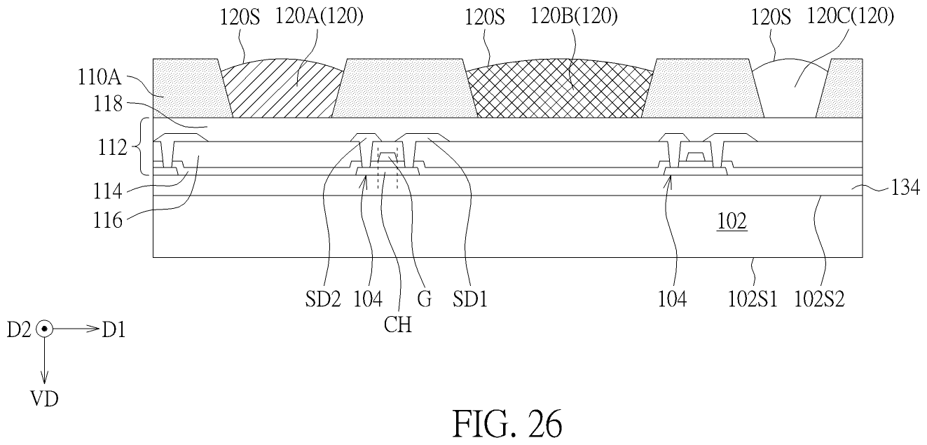

In some embodiments, as shown in FIG. 24, the upper surface 120S of at least one of the first color filter 120A, the second color filter 120B, and the third color filter 120C may have a concave structure. In other words, at least one of the first color filter 120A, the second color filter 120B, and the third color filter 120C may have a protruding portion 120P located on the first light blocking layer 110A. In some embodiments, as shown in FIG. 25, the first color filter 120A, the second color filter 120B, and the third color filter 120C may include ink materials. For example, the method of at least one of the first color filter 120A, the second color filter 120B, and the third color filter 120C may include following steps. At first, a colored or colorless and transparent ink material is formed in the opening OP11, the opening OP12, or the opening OP13 through an inkjet printing process or other suitable processes. In this step, the upper surface 120S of at least one of the first color filter 120A, the second color filter 120B, and the third color filter 120C is lower than the upper surface of the first light blocking layer 110A, for example, the thickness of the first color filter 120A, the thickness of the second color filter 120B, and the thickness of the third color filter 120C in the normal direction VD may be less than the thickness of the first light blocking layer 110A in the normal direction VD to prevent the ink material from overflow. Then, the post-baking process, an ultraviolet curing process, or other suitable processes at a temperature ranging from 100° C. to 250° C. is performed to cure the ink material, thereby forming at least one of the first color filter 120A, the second color filter 120B, and the third color filter 120C. Next, a de-gas process is performed to remove or release water, oxygen or ions in the formed first color filter 120A, second color filter 120B, and third color filter 120C, thereby reducing influence of water, oxygen or ions on the color conversion elements 108 and/or the light emitting elements 106 formed in the following steps. In some embodiments, the ink material may have a high concentration of solid content, for example, the content of the colored solid filter material may be higher than the content of liquid solvent. In some embodiments, when the first color filter 120A, the second color filter 120B, and the third color filter 120C include ink materials, each of the first color filter 120A, the second color filter 120B and the third color filter 120C may have a flat or concave upper surface 120S. In some embodiments, as shown in FIG. 26, when the first color filter 120A, the second color filter 120B, and the third color filter 120C include ink materials, each of the first color filter 120A, the second color filter 120B and the third color filter 120C may have an upper surface 120S protruding upward.

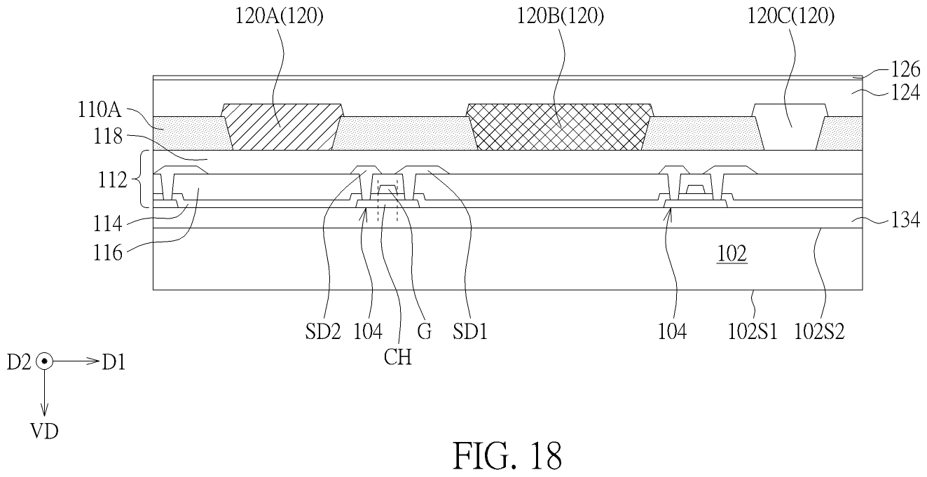

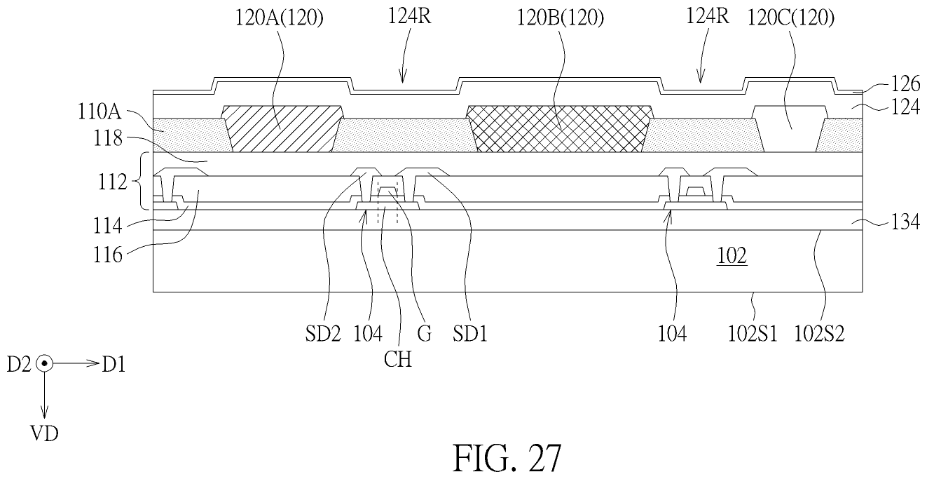

As shown in FIG. 18, after the first color filter 120A, the second color filter 120B, and the third color filter 120C are formed, the planarization layer 124 may be formed on the first color filter 120A, the second color filter 120B, the third color filter 120C and the first light blocking layer 110A. In the embodiment of FIG. 18, the planarization layer 124 may have a flat upper surface, but not limited thereto. In some embodiments, after the planarization layer 124 is formed, the protection layer 126 may be optionally formed on the planarization layer 124. In some embodiments, as shown in FIG. 27, the planarization layer 124 may be formed on the upper surfaces of the first color filter 120A, the second color filter 120B, the third color filter 120C, and the first light blocking layer 110A and have an uneven surface. For example, when the thicknesses of the first color filter 120A, the second color filter 120B, and the third color filter 120C in the normal direction VD are greater than that of the first light blocking layer 110A in the normal direction VD, the planarization layer 124 may have a recess 124R located on the first light blocking layer 110A. In some embodiments, when the thicknesses of the first color filter 120A, the second color filter 120B, and the third color filter 120C are less than that of the first light blocking layer 110A, the planarization layer 124 may have the recess located on the first color filter 120A, the second color filter 120B, and the third color filter 120C. In some embodiments of FIG. 27, the protection layer 126 may be formed on the planarization layer 124 along with ups and downs of the upper surface of the planarization layer 124, so that the protection layer 126 may also have a recess corresponding to the first light blocking layer 110A. In some embodiments, the planarization layer 124 may be formed on a surface formed by the first color filter 120A, the second color filter 120B, the third color filter 120C, and the first light blocking layer 110A in one of FIG. 24 to FIG. 26, and have an uneven surface.

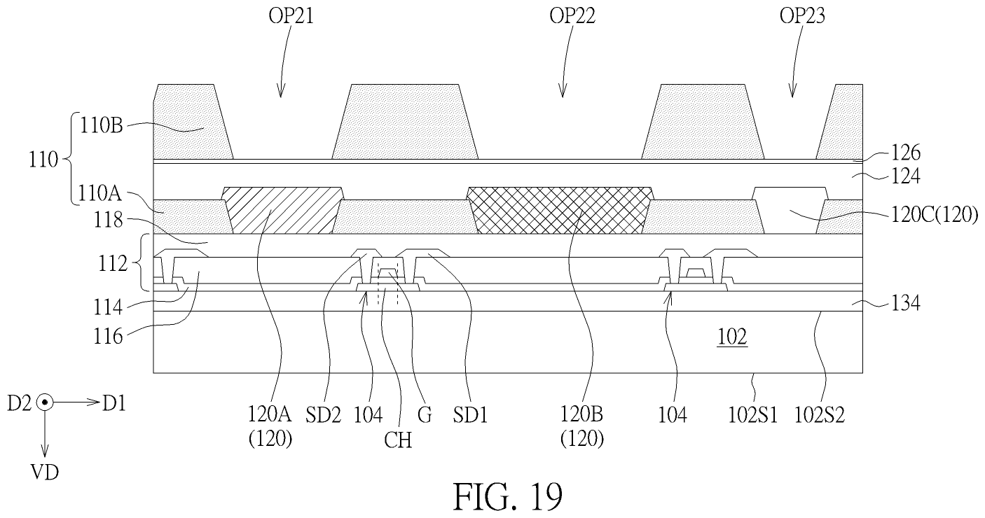

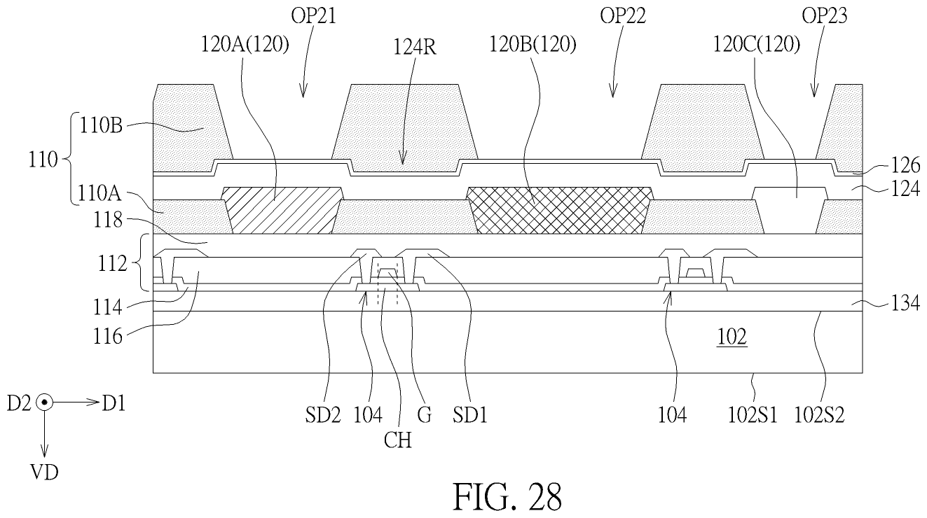

As shown in FIG. 19, the second light blocking layer 110B is formed on the planarization layer 124 or the protection layer 126. The method of forming the second light blocking layer 110B may include following steps, for example. At first, a light blocking photoresist is formed on the protection layer 126 by the spin coating process, the slit coating process or other suitable processes. Then, the light blocking photoresist may be dried, for example, through the vacuum drying process. Then, a pre-baking process is performed on the light blocking photoresist at a temperature ranging from 70° C. to 100° C. Then, an exposure process and a development process are performed on the light blocking photoresist through a photomask to form an opening OP21, an opening OP22, and an opening OP23, in which the opening OP21, the opening OP22, and the opening OP23 may overlap the opening OP11, the opening OP12, and the opening OP13 in the normal direction VD, respectively. Then, a post-baking process is performed at a temperature ranging from 200° C. to 250° C. to form the second light blocking layer 110B. A shape of the formed second light blocking layer 110B in the cross-sectional direction (e.g., the first direction D1 or the second direction D2) may be rectangular, trapezoid or other suitable shapes. It should be noted that a top-view area of the opening OP21 and a top-view area of the opening OP22 may be different from each other, for example, the widths of the opening OP21 and the opening OP22 in the same cross-sectional direction may be different from each other, so as to control the brightness of light of different colors emitted from the opening OP21 and the opening OP22 to match each other and meet the requirements. For example, an overlapping area of the opening OP21 and the opening OP11 in the normal direction VD may be different from that of the opening OP22 and the opening OP12 in the normal direction VD, so that the brightness of light emitted downward from the opening OP11 and the opening OP12 may be matched and mixed to meet required color. In some embodiments, a top-view area of the opening OP23 may be different from the top-view area of the opening OP21 and the top-view area of the opening OP22, but not limited thereto. In some embodiments, the width of one of the opening OP21, the opening OP22, and the opening OP23 may be less than the width of a corresponding one of the opening OP11, the opening OP12, and the opening OP13, but not limited thereto. In some embodiments, as shown in FIG. 28, when the planarization layer 124 or the protection layer 126 has the recess 124R located on the first light blocking layer 110A, the second light blocking layer 110B may be disposed in the recess 124R.

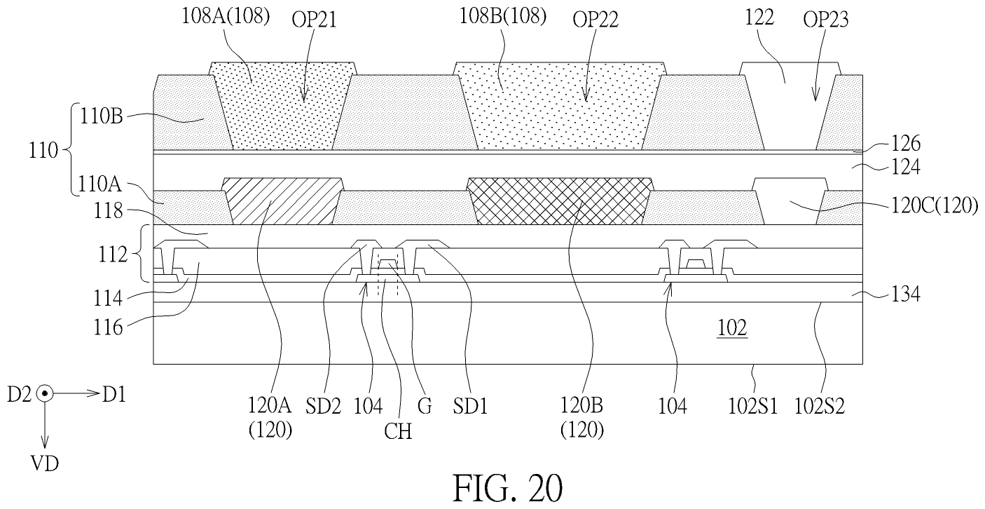

Next, as shown in FIG. 20, the first color conversion element 108A is formed in the opening OP21, the second color conversion element 108B is formed in the opening OP22, and the filling element 122 is formed in the opening OP23. In the embodiment of FIG. 20, the first color conversion element 108A, the second color conversion element 108B, and the filling element 122 may respectively partially extend to the upper surface of the second light blocking layer 110B, and each of which may have a thickness greater than the thickness of the second light blocking layer 110B. In one embodiment, the first color conversion element 108A, the second color conversion element 108B, and the filling element 122 may include photoresist materials, and the materials of the first color conversion element 108A and the second color conversion element 108B may include phosphor materials, fluorescent materials, quantum dots or other suitable color conversion materials capable of converting the color of light. For example, the method of forming at least one of the first color conversion element 108A, the second color conversion element 108B, and the filling element 122 may include following steps. At first, through a spin coating process, a slit coating process or other suitable processes, a photoresist material including the color conversion material capable of converting the color of light is formed in the opening OP21 or the opening OP22, or a colorless and transparent photoresist material is formed in the opening OP23. Then, the photoresist material is dried, for example, through a vacuum drying process. Next, a pre-baking process is performed on the photoresist material at a temperature ranging from 70° C. to 100° C. After that, an exposure process and a development process are performed on the photoresist material through a photomask, so as to keep the photoresist material in the opening OP21, the opening OP22, or the opening OP23. Then, the photoresist material is irradiated with infrared light to remove water, oxygen or ions in the photoresist material near the upper surface of the photoresist material. In some embodiments, the method of removing water, oxygen or ions is not limited to irradiation with infrared light, and other suitable methods may be used. Subsequently, a post-baking process is performed at a temperature ranging from 200° C. to 250° C. to form one of the first color conversion element 108A, the second color conversion element 108B, and the filling element 122. Then, the above steps are repeated at least twice to form the others of the first color conversion element 108A, the second color conversion element 108B, and the filling element 122. Then, a de-gas process is performed to remove or release water, oxygen or ions in the formed first color conversion element 108A, second color conversion element 108B, filling element 122, and second light blocking layer 110B, thereby reducing influence of water, oxygen or ions on the formed color conversion elements 108 and/or the light emitting elements 106 formed subsequently.

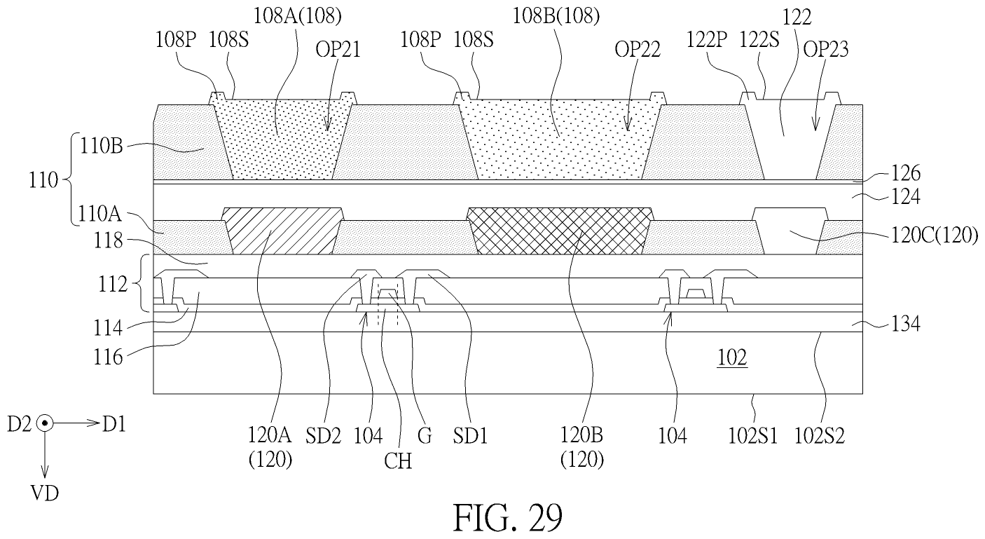

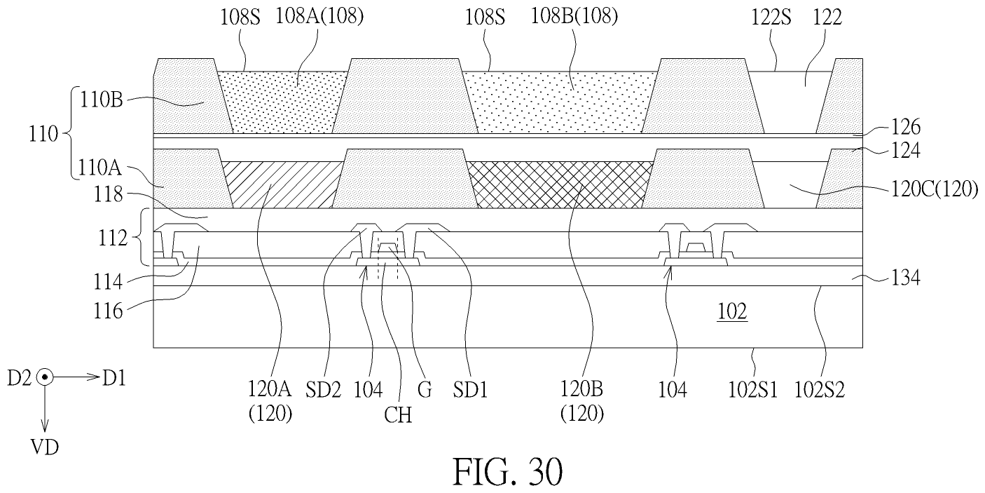

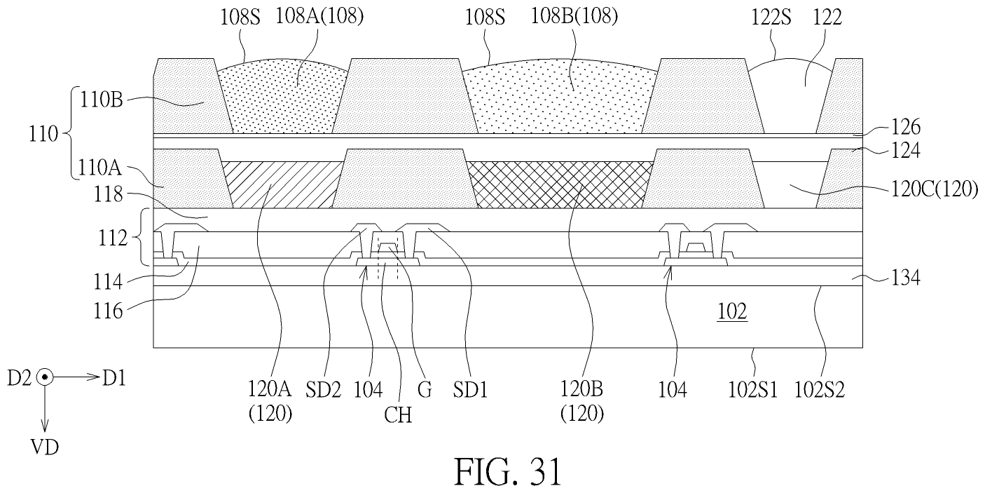

In some embodiments, as shown in FIG. 29, the upper surface 108S of at least one of the first color conversion element 108A and the second color conversion element 108B may have a concave structure. In other words, at least one of the first color conversion element 108A and the second color conversion element 108B may have a protruding portion 108P on the second light blocking layer 110B. In some embodiments, the upper surface 122S of the filling element 122 may also have a concave structure, and the filling element 122 may have a protruding portion 122P located on the second light blocking layer 110B. In some embodiments, as shown in FIG. 30, the first color conversion element 108A, the second color conversion element 108B and the filling element 122 may include ink materials. The method of forming at least one of the first color conversion element 108A, the second color conversion element 108B and the filling element 122 may include following steps, for example. At first, an ink material including a color conversion material or having colorless transparency is formed in the opening OP21, the opening OP22 or the opening OP23 through an inkjet printing or other suitable processes, in which the color conversion material may include phosphor material, fluorescent material, quantum dots or other suitable materials. In this step, the upper surfaces 108S of the first color conversion element 108A and the second color conversion element 108B and the upper surface 122S of the filling element 122 are lower than the upper surface of the first light blocking layer 110A. For example, the thicknesses of the first color conversion element 108A, the second color conversion element 108B, and the filling element 122 in the normal direction VD are smaller than that of the second light blocking layer 110B in the normal direction VD, so as to avoid overflow of the ink material. Then, a post-baking process, an ultraviolet curing process or other suitable processes is performed at a temperature ranging from 90° C. to 125° C. to cure the ink material and form one of the first color conversion element 108A, the second color conversion element 108B, and the filling element 122. Following that, the above steps are repeated at least twice to form the others of the first color conversion element 108A, the second color conversion element 108B, and the filling element 122. Then, a de-gas process is performed to remove or release water, oxygen or ions in the formed first color conversion element 108A, second color conversion element 108B and filling element 122, thereby reducing the influence of water, oxygen or ions on the color conversion elements 108 and/or light emitting elements 106 formed subsequently. In some embodiments, when the first color conversion element 108A, the second color conversion element 108B, and the filling element 122 include ink materials, the upper surfaces 108S of the first color conversion element 108A and the second color conversion element 108B and the upper surface 122S of the filling element 122 may respectively have a flat structure or a concave structure. In some embodiments, as shown in FIG. 31, when the first color conversion element 108A, the second color conversion element 108B, and the filling element 122 include ink materials, the first color conversion element 108A, the second color conversion element 108B, and the filling element 122 may respectively have a protruding upward upper surface. In some embodiments, the first color conversion element 108A, the second color conversion element 108B, and the filling element 122 formed in any one of FIG. 20, FIG. 29, FIG. 30 and FIG. 31 may be combined with the first color filter 120A, the second color filter 120B and the third color filter 120C formed in any one of FIG. 17, FIG. 24, FIG. 25 and FIG. 26 or the structure shown in FIG. 28.

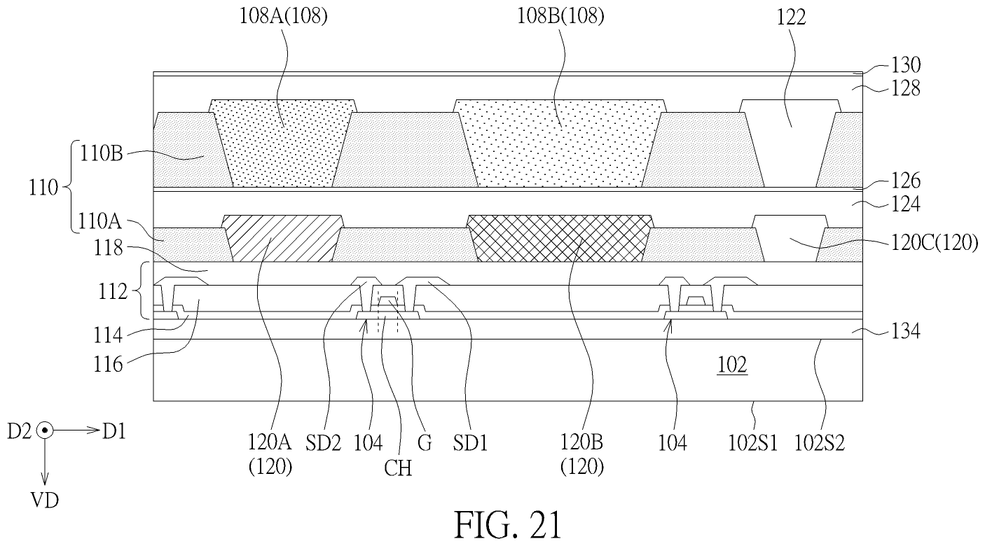

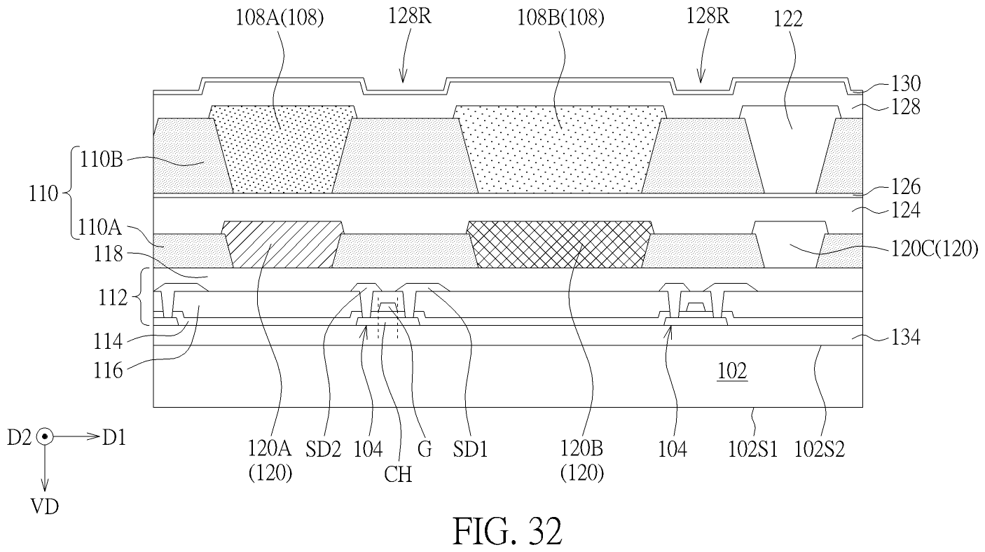

As shown in FIG. 21, after the first color conversion element 108A, the second color conversion element 108B, and the filling element 122 are formed, the planarization layer 128 is formed on the first color conversion element 108A, the second color conversion element 108B, and the filling element 122. In the embodiment of FIG. 21, the planarization layer 128 may have a flat upper surface, but not limited thereto. In some embodiments, after the planarization layer 128 is formed, the protection layer 130 may be optionally formed on the planarization layer 128. In some embodiments, as shown in FIG. 32, the planarization layer 128 may be formed on the upper surfaces of the first color conversion element 108A, the second color conversion element 108B, the filling element 122, and the second light blocking layer 110B to have an uneven surface. For example, when the thicknesses of the first color conversion element 108A, the second color conversion element 108B, and the filling element 122 are greater than the thickness of the second light blocking layer 110B, the planarization layer 128 may have a recess 128R located on the second light blocking layer 110B. In some embodiments, when the thicknesses of the first color conversion element 108A, the second color conversion element 108B, and the filling element 122 are less than the thickness of the second light blocking layer 110B, the planarization layer 128 may have a recess located on the first color conversion element 108A, the second color conversion element 108B, and the filling element 122. In some embodiments of FIG. 32, the protection layer 130 may be formed on the planarization layer 128 along with the up-and-down upper surface of the planarization layer 128 to have a recess corresponding to the second light blocking layer 110B. In some embodiments, the planarization layer 128 may also be formed on the upper surfaces of the first color conversion element 108A, the second color conversion element 108B, the filling element 122, and the second light blocking layer 110B of any one of FIG. 29 to FIG. 31 to have an uneven surface. surface. In some embodiments, the planarization layer 128 and the protection layer 130 formed in any one of FIG. 21 and FIG. 32 may be combined with the first color filter 120A, the second color filter 120B, and the third color filter 120C formed in any one of FIG. 17, FIG. 24, FIG. 25, and FIG. 26, the structure shown in FIG. 28 or the first color conversion element 108A, the second color conversion element 108B, and the filling element 122 formed in any one of FIG. 20, FIG. 29, FIG. 30, and FIG. 31.

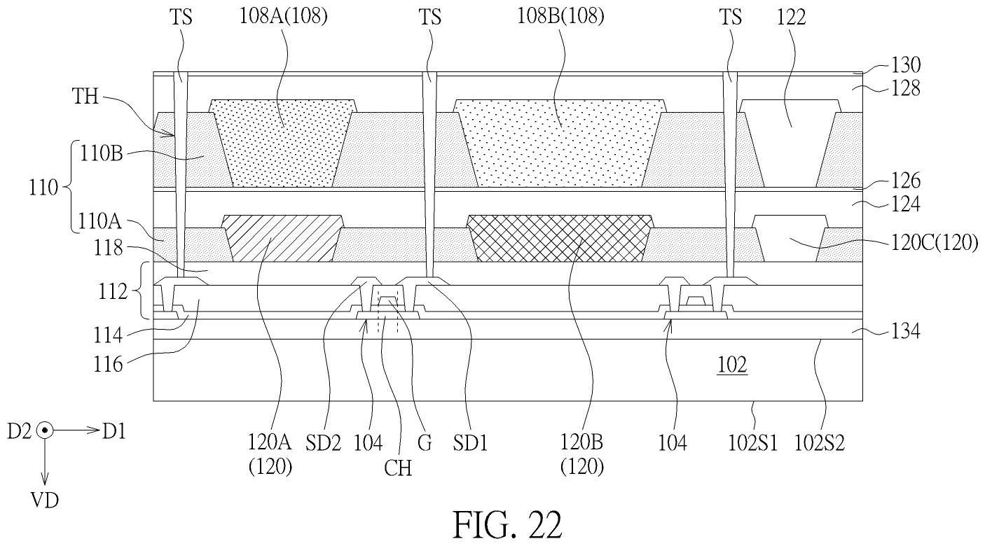

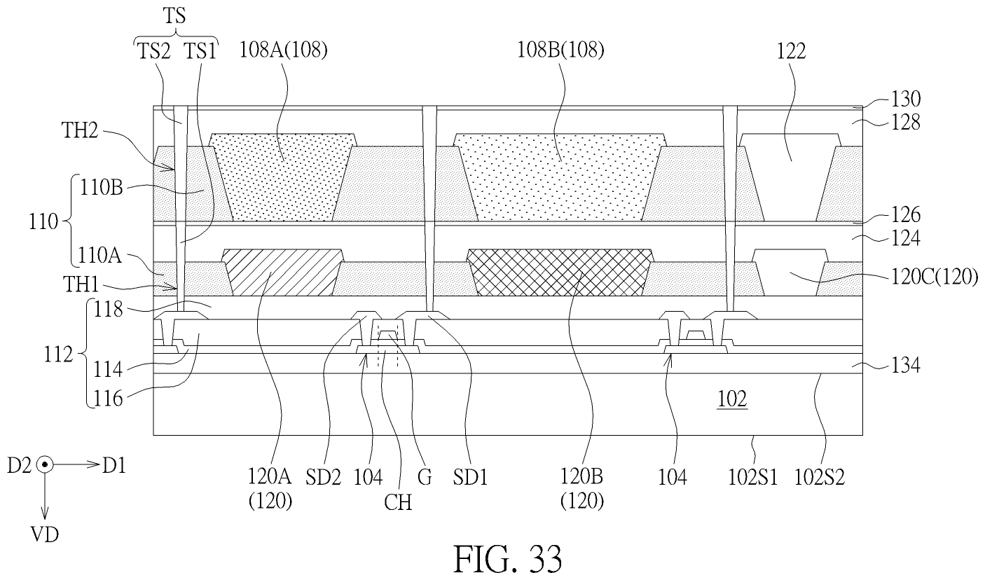

As shown in FIG. 22, after the planarization layer 128 (or the protection layer 130) is formed, a plurality of through holes TH penetrating through the planarization layer 128, the second light blocking layer 110B, the planarization layer 124, the first light blocking layer 110A, and the planarization layer 118 may be formed to expose the source(drain) electrodes SD1, respectively. The method of forming the through holes TH may, for example, include at least one of laser etching, dry etching, wet etching, or other suitable methods. Next, a plurality of via structures TS are respectively formed in the through holes TH, where the via structures TS may include conductive materials, and the conductive material may include, for example, nanosilver glue, conductive particles, conductive fluid materials, or other suitable conductive materials. In some embodiments, when the protection layer 130 is formed on the planarization layer 128, and the protection layer 126 is formed on the planarization layer 124, the through holes TH may also penetrate through the protection layer 130 and the protection layer 126. In some embodiments, as shown in FIG. 33, one of the via structures TS may include a multilayer structure. The via structure TS is a two-layer structure as an example, and the via structure TS may include a first via structure TS1 and a second via structure TS2 disposed on the first via structure TS1. The first via structure TS1 may be formed after the planarization layer 124 (or the protection layer 126) is formed and before forming the second light blocking layer 110B. The second via structure TS2 may be formed after the planarization layer 128 (or the protection layer 130) is formed. The method of forming the first via structure TS1 may include, for example, forming a through hole TH1 in the planarization layer 124, the first light blocking layer 110A, and the planarization layer 118 first, and then forming a conductive material in the through hole TH1. The method of forming the second via structure TS2 may include, for example, forming a through hole TH2 in the planarization layer 128 and the second light blocking layer 110B, and then forming a conductive material in the through hole TH2. Since the via structure TS needs to penetrate through layers with a certain thickness, an upper surface area of the via structure TS may be reduced through the multi-layer via structure TS. In some embodiments, when the protection layer 126 is formed on the planarization layer 124, the through hole TH1 may also penetrate through the protection layer 126. When the protection layer 130 is formed on the planarization layer 128, the through hole TH2 may also penetrate through the protection layer 130. In some embodiments, the number of layers of the via structure TS may be adjusted according to requirements.

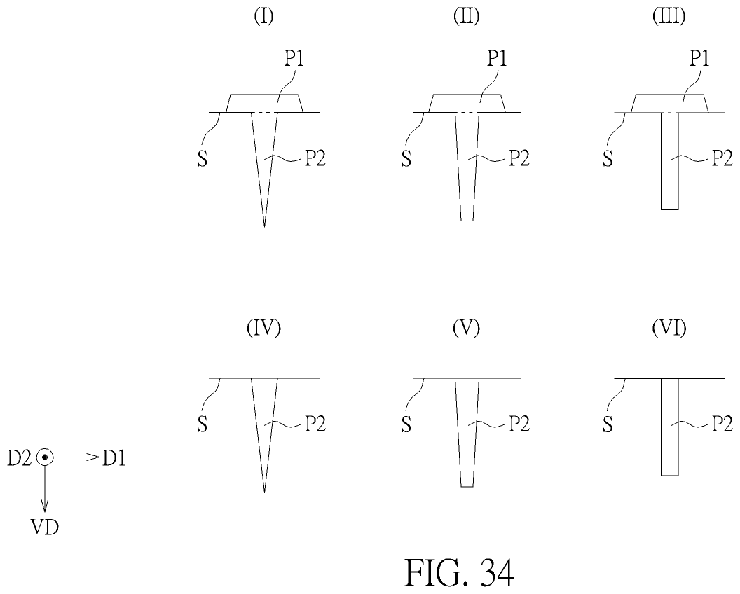

In some embodiments, as shown in a part (I), a part (II), and a part (III) of FIG. 34 and FIG. 22, the via structure TS may, for example, include an upper part P1 and a lower part P2, wherein the upper part P1 is disposed on the lower part P2 and on the corresponding upper surface S of the planarization layer 128 or the protection layer 130, and the lower part P2 is disposed in the through hole TH. In addition, a width of the upper part P1 in the cross-sectional direction is greater than a width of the lower part P2 in the cross-sectional direction or a width of a top opening of the through hole TH, so as to facilitate the electrical connection between the via structure TS and element formed subsequently, for example, to facilitate the electrical connection to the first electrode 106A of the light emitting element 106. A shape of the lower portion P2 in the cross-sectional direction (e.g., the first direction D1 or the second direction D2) may be, for example, triangle, inverted trapezoid, rectangle, or other suitable shapes. In some embodiments, as shown in a part (IV), a part (V), and a part (VI) of FIG. 34 and FIG. 22, the via structure TS may be disposed in the through hole TH and formed of the lower part P2. In such case, a shape of the lower portion P2 in the cross-sectional direction may be, for example, triangle, inverted trapezoid, rectangle, or other suitable shapes. In some embodiments, the first via structure TS1 and/or the second via structure TS2 shown in FIG. 33 may include the upper part P1 and the lower part shown in one of the part (I), the part (II), and the part (III) of FIG. 34. When the first via structure TS1 has the upper part P1 and the lower part P2 shown in the part (I), the part (II), and the part (III) of FIG. 34, the second via structure TS2 may still be electrically connected to the first via structure TS1 in a situation that there is a large error in the alignment between the through hole TH1 and the through hole TH2. In such case, the width of the upper part P1 in the cross-sectional direction may be greater than the width of the lower part P2 in the cross-sectional direction or a width of a top opening of the through hole TH1 or the through hole TH2 shown in FIG. 33. In some embodiments, the first via structure TS1 and/or the second via structure TS2 may be formed of the lower part P2 shown in the part (IV), the part (V), and the part (VI) of FIG. 34. In some embodiments, the first via structure TS1 and/or the second via structure TS2 may be composed of the upper part P1 and the lower part P2 shown in the part (I), the part (II) and the part (III) of FIG. 34. In some embodiments, any one of the via structures shown in FIG. 22, FIG. 33, and FIG. 34 may be combined with the first color filter 120A, the second color filter 120B, and the third color filter 120C formed in any of FIG. 17, FIG. 24, FIG. 25, and FIG. 26, the structure shown in FIG. 28, the first color conversion element 108A, the second color conversion elements 108B, and the filling element 122 formed in any one of FIG. 20, FIG. 29, FIG. 30, and FIG. 31, or the planarization layer 128 and the protection layer 130 formed in any one of FIG. 21 and FIG. 32. In some embodiments, any via structure shown in FIG. 34 may be applied to any of the above embodiments.

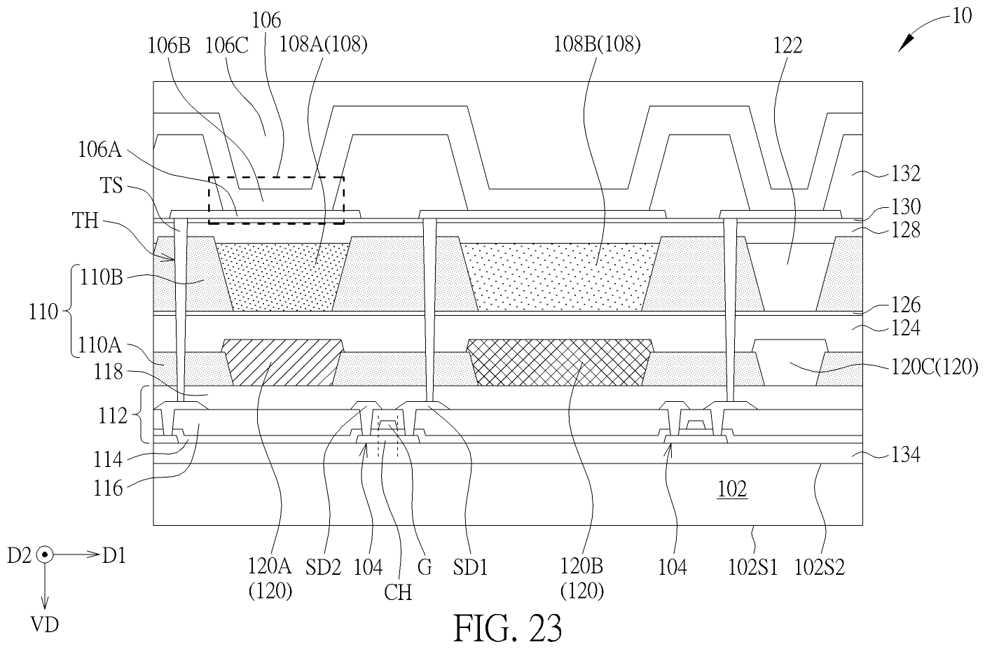

As shown in FIG. 23, after the via structures TS are formed, the first electrodes 106A are formed on the protection layer 130 and the via structures TS, so that the first electrodes 106A may be electrically connected to the corresponding active elements 104 through the corresponding via structures TS. Then, a pixel defining layer 132 is formed on the first electrodes 106A and the protection layer 130, in which the pixel defining layer 132 may include a plurality of openings OPP corresponding to a plurality of light emitting regions. A thickness of the pixel defining layer 132 may be greater than the thickness of one of the first electrodes 106A. The optical density (OD) of the pixel defining layer 132 may be, for example, greater than 2.5 to achieve a function of shielding light or blocking light from penetration. For example, the material of the pixel defining layer 132 may include light-absorbing material, light-reflecting material or other suitable materials, such as photoresist material, but not limited thereto. The method of forming the pixel defining layer 132 may include, for example, a spin coating process or a slit coating process. In some embodiments, the pixel defining layer 132 may have high resistance, but not limited thereto. Next, the light emitting layer 106B is formed on the pixel defining layer 132 and the first electrodes 106A, and then the second electrode 106C is formed on the light emitting layer 106B, thereby forming the light emitting elements 106. The method of forming the light emitting layer 106B may include, for example, a physical vapor deposition process, a chemical vapor deposition process, an inkjet process, or other suitable processes. In the display device 10 shown in FIG. 23, the second electrode 106C may have a flat upper surface, but not limited thereto. Since the first electrodes 106A, the light emitting layer 106B, and the second electrode 106C may be similar to or the same as the embodiment in FIG. 1, they will not be repeated herein. In some embodiments, as shown in FIG. 1, the upper surface of the second electrode 106C may have a recess. The manufacturing method of the tenth embodiment described above may be applied to the method of manufacturing the display device 1 shown in FIG. 1 or other suitable embodiments. In some embodiments, the first electrodes 106A in FIG. 23 and the second via structure TS2 shown in FIG. 33 may be formed of the same process. In some embodiments, the first electrodes 106A of FIG. 23 and the second via structure TS2 shown in FIG. 33 may be formed of the same material. In some embodiments, the first electrodes 106A in FIG. 23 and the second via structure TS2 shown in FIG. 33 may be formed using the same process and the same material. In some embodiments, any one of the light emitting elements 106 shown in FIG. 23 and FIG. 1 may be combined with the first color filter 120A, the second color filter 120B, and the third color filter 120C formed in any one of FIG. 17, FIG. 24, FIG. 25, and FIG. 26, the structure shown in FIG. 28, the first color conversion element 108A, the second color conversion element 108B, and the filling element 122 formed in any one of FIG. 20, FIG. 29, FIG. 30, and FIG. 31, the planarization layer 128 and the protection layer 130 formed in any one of FIG. 21 and FIG. 32, or any via structure shown in FIG. 22, FIG. 33, and FIG. 34.

In summary, in the display device of the present disclosure, since the light blocking element is disposed between the color conversion elements and the channels of the active elements, the channels of the active elements are not easily irradiated with the second light, thereby mitigating or avoiding electrical deviation (e.g., deviation of threshold voltage) or electric leakage of the active elements. As a result, the display device of the present disclosure may achieve the bottom emission function in the situation of having the color conversion elements.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A display device, comprising:
a substrate;
an active element containing a channel disposed on the substrate;
a light emitting element configured to be driven by the active element to emit a first light;
a color conversion element; and
a light blocking element;
which are so arranged that the first light emitted from the light emitting element passes through the color conversion element to be converted into a second light which then passes through the substrate, and the channel of the active element is protected by the light blocking element from at least a majority of the second light.

2. The display device according to claim 1, further comprising a color filter.

3. The display device according to claim 2, wherein the color conversion element and the color filter are disposed on a same side of the substrate.

4. The display device according to claim 3, wherein the color filter is disposed between the substrate and the color conversion element.

5. The display device according to claim 2, wherein the color filter and the color conversion element are disposed on opposite sides of the substrate.

6. The display device according to claim 1, wherein the active element is a thin film transistor.

7. The display device according to claim 1, wherein the first light is a blue light.

8. The display device according to claim 1, wherein the second light has a longer peak wavelength in comparison with the first light.

9. The display device according to claim 1, wherein the light emitting element is an organic light emitting diode.
